(19) United States
(12) Patent Application Publication
(10) Pub. No.: US 2025/0046741 A1
(43) Pub. Date: Feb. 6, 2025

(54) SEMICONDUCTOR DEVICE

(71) Applicant: Renesas Electronics Corporation, Tokyo (JP)

(72) Inventors: Keita TSUCHIYA, Tokyo (JP); Shuuichi KARIYAZAKI, Tokyo (JP); Kazuo SAKAMOTO, Tokyo (JP)

(21) Appl. No.: 18/775,102

(22) Filed: Jul. 17, 2024

(30) Foreign Application Priority Data
Aug. 1, 2023 (JP) 2023-125203

(51) Int. Cl. H01L 23/00; H01L 23/498; H01L 23/528

(52) U.S. Cl. CPC H01L 24/14; H01L 23/49822; H01L 23/5286; H01L 24/04; H01L 24/16; H01L 24/32; H01L 24/73; H01L 2224/0401; H01L 2224/14132; H01L 2224/14133; H01L 2224/16225; H01L 2224/32225; H01L 2224/73204; H01L 2924/1517

(57) ABSTRACT

The performance of a semiconductor device can be improved. A plurality of protruding electrodes of a semiconductor chip includes: a plurality of first protruding electrodes arranged at positions overlapping a first region of an insulating layer, a plurality of second protruding electrodes arranged at positions overlapping a second region of the insulating layer, and a plurality of third protruding electrodes arranged at positions overlapping a third region of the insulating layer. The plurality of first protruding electrodes is arranged at a first pitch, the plurality of second protruding electrodes is arranged at a second pitch, and the plurality of third protruding electrodes is arranged at a third pitch different from each of the first pitch and the second pitch.

### CROSS-REFERENCE TO RELATED APPLICATIONS

The disclosure of Japanese Patent Application No. 2023-125203 filed on Aug. 1, 2023, including the specification, drawings and abstract is incorporated herein by reference in its entirety.

### BACKGROUND

The present invention relates to a semiconductor device.

There are disclosed techniques listed below.
[Patent Document 1] Japanese Unexamined Patent Application Publication No. 2019-75442

There is a semiconductor device in which a semiconductor chip is mounted on a wiring substrate including a plurality of wiring layers by a flip-chip connection method. For example, Patent Document 1 discloses a structure in which a semiconductor chip and a wiring substrate are electrically connected with each other via a plurality of protruding electrodes arranged on a surface of the semiconductor chip.

### SUMMARY

In accordance with the advancement of a semiconductor device, there is a tendency for the number of protruding electrodes of one semiconductor chip to increase. On the other hand, due to the demand for miniaturization of a semiconductor chip, the arrangement density of the protruding electrodes is to be high. Therefore, it is necessary to arrange the protruding electrodes so as not to occur an electrical short-circuit between adjacent protruding electrodes with each other. The present inventors have found that, from the viewpoint of improving the reliability or improving the electrical characteristics of the semiconductor device, it may be improved by devising the arrangement of the protruding electrodes, compared to the case where the protruding electrodes are simply arranged at a minimum pitch.

Other objects and novel features will become apparent from the description of this specification and the accompanying drawings.

A semiconductor chip of a semiconductor device according to one embodiment includes: a first wiring layer formed on a semiconductor substrate; a second insulating layer arranged so as to cover the first wiring layer; and a plurality of protruding electrodes electrically connected with the first wiring layer. The plurality of protruding electrodes includes: a plurality of first protruding electrodes arranged at positions overlapping a first region of the second insulating layer; a plurality of second protruding electrodes arranged at positions overlapping a second region of the second insulating layer; and a plurality of third protruding electrodes arranged at positions overlapping a third region of the second insulating layer. The plurality of first protruding electrodes is arranged at a first pitch, the plurality of second protruding electrodes is arranged at a second pitch, and the plurality of third protruding electrodes is arranged at a third pitch different from each of the first pitch and the second pitch. A component in a second direction of the second pitch is larger than a component in the second direction of the first pitch.

According to the embodiment, the performance of the semiconductor device can be improved.

### BRIEF DESCRIPTION OF THE DRAWINGS

FIG. 1 is a plan view of an upper surface of a semiconductor device according to one embodiment.

FIG. 2 is a plan view of a lower surface of the semiconductor device shown in FIG. 1.

FIG. 3 is a cross-sectional view along a line A-A shown in FIG. 1.

FIG. 4 is an explanatory diagram showing an example of the configuration of a circuit provided in the semiconductor device shown in FIGS. 1 to 3.

FIG. 5 is a plan view of an electrode arrangement surface of a semiconductor chip shown in FIG. 3.

FIG. 6 is an enlarged plan view at a part A shown in FIG. 5.

FIG. 7 is a plan view showing an examined example in relation to a layout of protruding electrodes shown in FIG. 5.

FIG. 8 is a plan view showing another examined example in relation to the layout of the protruding electrodes shown in FIG. 5.

FIG. 9 is an enlarged cross-sectional view along a line B-B shown in FIG. 6.

FIG. 10 is an enlarged plan view at a part B shown in FIG. 5.

FIG. 11 is a plan view of an electrode arrangement surface of a semiconductor chip, which is a modified example in relation to FIG. 5.

FIG. 12 is an enlarged plan view at a part C shown in FIG. 11.

FIG. 13 is an enlarged plan view showing an example of a layout of a wiring layer, which is located in the top layer, of a wiring substrate on which the semiconductor chip shown in FIGS. 11 and 12 is mounted.

FIG. 14 is a plan view of an electrode arrangement surface of a semiconductor chip, which is another modified example in relation to FIG. 5.

FIG. 15 is an enlarged plan view at a part D shown in FIG. 14.

FIG. 16 is an explanatory diagram showing an example of a flow of a method of manufacturing the semiconductor device shown in FIG. 3.

FIG. 17 is a plan view schematically showing a direction of sending wind in the drying process shown in FIG. 16.

### DETAILED DESCRIPTION

### Explanation of Description Format, Basic Terms, and Usage in this Application

In this application, descriptions of embodiments are divided into multiple sections or the like for convenience, as necessary, except when expressly stated otherwise, these are not independent from each other, and each part of a single example, one of which is a detailed part or a part or all of a modified example of the other, regardless of the order of description. In principle, descriptions of similar parts are omitted. Also, each component in an embodiment is not essential, unless expressly stated otherwise, theoretically limited to that number, and obviously not so from the context.

Similarly, in the description of embodiments and the like, “X consisting of A” or the like with respect to materials, compositions, etc., does not exclude those containing elements other than A, except when expressly stated otherwise and when it is obvious from the context that this is not the case. For example, regarding components, it means “X including A as a main component” or the like. For example, even when referred to as “silicon member” or the like, it is not limited to pure silicon, but also includes SiGe (Silicon Germanium) alloys and other multi-component alloys with silicon as the main component, and other additives. Also, when referred to as gold plating, Cu layer, nickel plating, etc., unless expressly stated otherwise, it includes not only pure ones but also members with gold, Cu, nickel, etc. as main components.

Furthermore, when referring to specific numerical values or quantities, unless expressly stated otherwise, theoretically limited to that number, and obviously not so from the context, the value may be greater than or less than that specific numerical value.

In the drawings of the embodiments, the same or similar parts are denoted by the same or similar symbols or reference numerals, and the description will not be repeated in principle.

In the attached drawings, hatching and the like may be omitted even in a cross-section when it becomes complicated or when it is clearly distinguished from a gap. In this connection, even if the hole is closed in plan, the outline of the background may be omitted when it is obvious from the description or the like. Furthermore, even if it is not a cross-section, hatching or a dot pattern may be added to indicate that it is not a gap or to indicate the boundary of a region.

In the following description, a semiconductor chip electrode refers to a member that functions as an external terminal of the semiconductor chip. Among the electrodes, a small plate-like member in terms of area is referred to as an “electrode pad”. Among the electrodes, a member that is formed to protrude locally from the substrate is referred to as a “bump electrode” or “protruding electrode”. Also, either “electrode pad” or “bump electrode (or protruding electrode)” may simply be referred to as an “electrode”.

Also, a structure in which a bump electrode (or protruding electrode) is formed on an electrode pad may be referred to as an “electrode”.

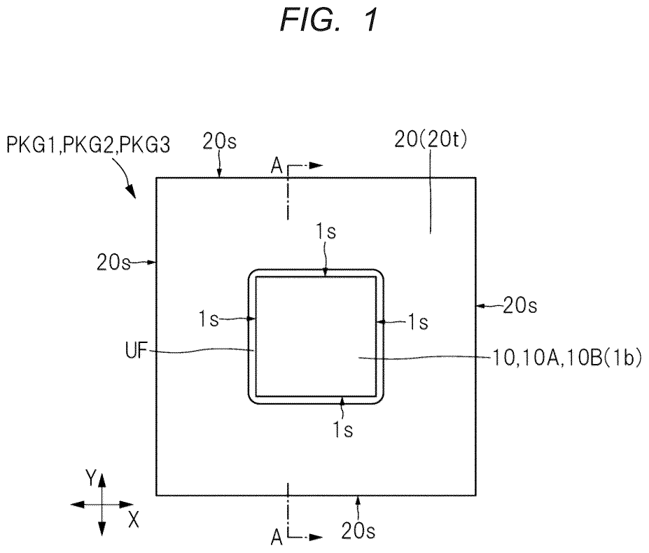

In the following description, the directions of X, Y, and Z may be used. For example, as will be described later in FIG. 1, the X direction and the Y direction are shown. The X direction and the Y direction intersect each other. In the example described below, the X direction is orthogonal to the Y direction.

Hereinafter, the X-Y plane including the X direction and the Y direction will be described as a plane parallel to the main surface of the semiconductor device and the main surface of the mounting substrate.

A surface intersecting the X-Y plane (for example, a surface parallel to the X-Z plane including the X direction and the Z direction, and a surface parallel to the Y-Z plane including the Y direction and the Z direction) is referred to as a side surface. In the following description, unless otherwise explicitly stated, the term “plan view” refers to a view of a plane parallel to the X-Y plane. Also, the normal direction to the X-Y plane is described as the “Z direction” or the thickness direction. The terms “thickness” and “height” refer to the length in the “Z direction”, unless otherwise explicitly stated. The X, Y, and Z directions intersect each other, and more specifically, they are orthogonal to each other.

### <Semiconductor Device>

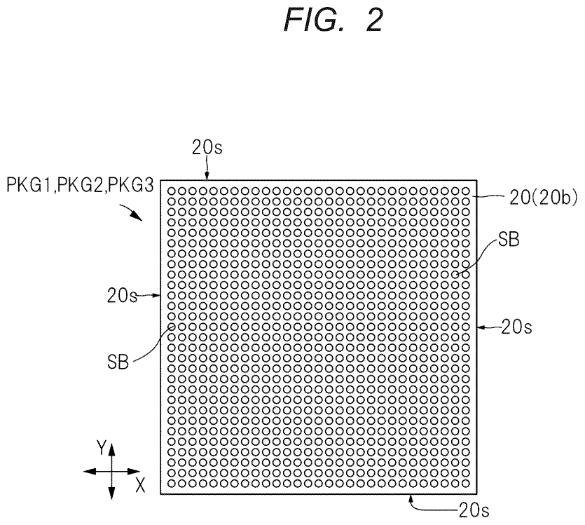

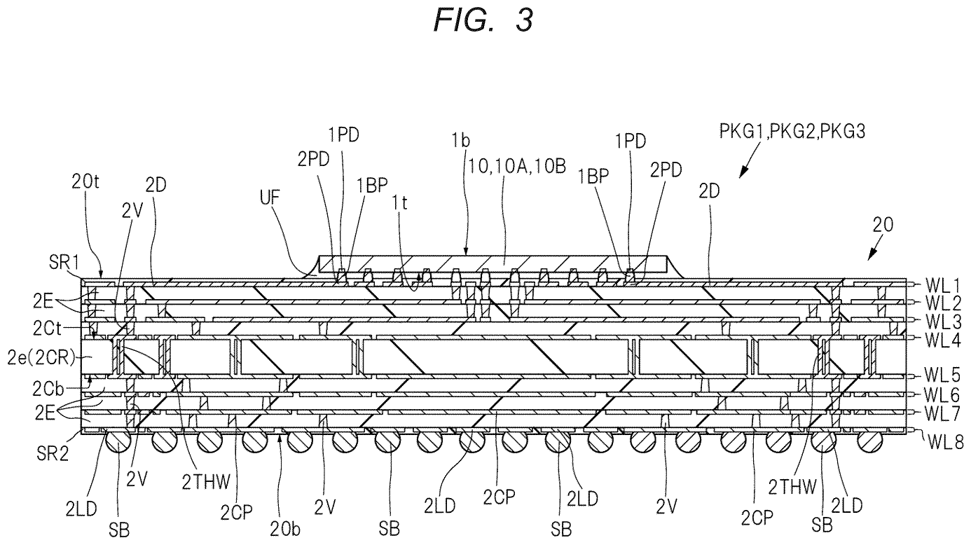

FIG. 1 is a plan view of an upper surface of a semiconductor device of the present embodiment. FIG. 2 is a plan view of a lower surface of the semiconductor device shown in FIG. 1. Furthermore, FIG. 3 is a cross-sectional view along a line A-A shown in FIG. 1. In FIG. 3, for ease of viewing, the number of electrodes 1PD and the number of protruding electrodes 1BP are shown less than in the plan view of a semiconductor chip described later.

The semiconductor device PKG1 of the present embodiment includes a wiring substrate 20 and a semiconductor chip 10 mounted on the wiring substrate 20 (see FIGS. 1 and 3). The semiconductor device PKG1 also has an underfill layer (insulating layer, insulating material) UF (see FIGS. 1 and 3) that is arranged between the semiconductor chip 10 and the wiring substrate 20 and seals a plurality of protruding electrodes 1BP (see FIG. 3).

As shown in FIG. 3, the wiring substrate 20 has an upper surface (surface, main surface, chip mounting surface) 20t on which the semiconductor chip 10 is mounted, and a lower surface (surface, main surface, mounting surface) 20b on the opposite side of the upper surface 20t. The wiring substrate 20 also has plurality of sides 20s (see FIGS. 1 and 2) that form the outer periphery of the upper surface 20t and the lower surface 20b in plan view. In the present embodiment, the upper surface 20t (see FIG. 1) and the lower surface 20b (see FIG. 2) of the wiring substrate 20 are each rectangular, and the wiring substrate 20 has four sides 20s in plan view.

The wiring substrate 20 also has a plurality of wiring layers (in the example shown in FIG. 3, there are 8 layers) WL1, WL2, WL3, WL4, WL5, WL6, WL7, and WL8 provided between the upper surface 20t and the lower surface 20b. The plurality of wiring layers include a wiring layer WL1 that is the closest layer to the upper surface 20t of the wiring substrate 20 among these wiring layers and has a terminal (terminal 2PD). The plurality of wiring layers also include a wiring layer WLB that is the closest layer to the lower surface 20b of the wiring substrate 20 among these wiring layers and has a terminal (land 2LD).

Each wiring layer has a conductor pattern such as a wiring 2D that serves as a path for supplying electrical signals and power. An insulating layer 2E is arranged between each wiring layer. Each wiring layer is electrically connected with each other through a via 2V, which is an interlayer conductive path that penetrates the insulating layer 2E, or a through-hole wiring 2THW. In the present embodiment, a wiring substrate having 8 wiring layers is exemplified as an example of the wiring substrate 20, but the number of wiring layers provided by the wiring substrate 20 is not limited to 8. For example, a wiring substrate having 7 or fewer layers or 9 or more layers can be used as a modified example.

Among the plurality of wiring layers, the wiring layer WL1, which is the layer closest to the upper surface 20t (top layer), is covered with an insulating film SR1. An opening is provided in the insulating film SR1, and the plurality of terminals 2PD provided on the wiring layer WL1 are exposed from the insulating film SR1 at the opening.

Among the plurality of wiring layers, the wiring layer WL8, which is the layer closest to the lower surface 20b of the wiring substrate 20 (bottom layer), has a plurality of lands 2LD. The wiring layer WL8 is covered with an insulating film SR2. An opening is provided in the insulating film SR2, and the plurality of lands 2LD provided on the wiring layer WL8 are exposed from the insulating film SR2 at the opening.

Each of the insulating films SR1 and SR2 is a solder resist film. The plurality of terminals 2PD provided in the wiring layer WL1 is electrically connected with the plurality of lands (land patterns) 2LD provided in the wiring layer WL8, the conductor patterns (wiring 2D and large-area conductor patterns) formed in each wiring layer provided by the wiring substrate 20, via 2V, and through-hole wiring 2THW.

The wiring substrate 20 is formed by laminating a plurality of wiring layers on the upper surface 2Ct and the lower surface 2Cb of the insulating layer (core material, core insulating layer) 2CR made of prepreg impregnated with resin, for example, using a build-up method. The wiring layer WL4 on the upper surface 2Ct side of the insulating layer 2CR and the wiring layer WL5 on the lower surface 2Cb side are electrically connected via a plurality of through-hole wirings 2THW embedded in a plurality of through-holes provided to penetrate from one of the upper surface 2Ct and the lower surface 2Cb to the other.

In the example shown in FIG. 3, the wiring substrate 20 shows a wiring substrate that has laminated a plurality of wiring layers on the upper surface 2Ct side and the lower surface 2Cb side of the insulating layer 2CR, which is a core material. However, as a modified example for FIG. 3, there is a case where a coreless substrate is used, which is formed by sequentially laminating an insulating layer 2E and conductor patterns such as wiring 2D without having an insulating layer 2CR made of hard materials such as prepreg. In the case of using a coreless substrate, the through-hole wiring 2THW is not formed, and each wiring layer is electrically connected via the via 2V.

In the example shown in FIG. 3, a solder ball (solder material, external terminal, electrode, external electrode) SB is connected to each of the plurality of lands 2LD. The solder ball SB is a conductive member that electrically connects a plurality of terminals (not shown) on the motherboard side and a plurality of lands 2LD when mounting the semiconductor device PKG1 on a motherboard (not shown).

The solder ball SB is, for example, a solder material made of Sn—Pb solder containing lead (Pb), or so-called lead-free solder that does not substantially contain Pb. Examples of lead-free solder include, for example, tin (Sn) only, tin-bismuth (Sn—Bi), tin-copper-silver (Sn—Cu—Ag), tin-copper (Sn—Cu), and the like. Here, lead-free solder means that the content of lead (Pb) is 0.1 wt or less, and this content is defined as a standard of the RoHS (Restriction of Hazardous Substances) directive.

As shown in FIG. 2, a plurality of solder balls SB are arranged in a matrix (array, matrix) form. Also, although not shown in FIG. 2, a plurality of lands 2LD (see FIG. 3) to which a plurality of solder balls SB is bonded is also arranged in a matrix (matrix) form. Thus, a semiconductor device that arranges a plurality of external terminals (solder balls SB, lands 2LD) in a matrix on the mounting surface side of the wiring substrate 20 is called an area array type semiconductor device.

The area array type semiconductor device is preferable in that it can effectively utilize the mounting surface (lower surface 20b) side of the wiring substrate 20 as a placement space for external terminals, and can suppress an increase in the mounting area of the semiconductor device even if the number of external terminals increases. In other words, it is possible to mount a semiconductor device with an increased number of external terminals due to high functionality and high integration in a space-saving manner.

The semiconductor device PKG1 includes the semiconductor chip 10 mounted on the wiring substrate 20. As shown in FIG. 3, each of the semiconductor chips 10 has a front surface (surface, main surface, upper surface) it and a back surface (surface, main surface, rear surface, lower surface) lb opposite to the front surface 1t. The semiconductor chip 10 has a plurality of sides is (see FIG. 1) that constitute the outer edges of each of the front surface it and the back surface 1b in plan view. The semiconductor chip 10 has a rectangular outer shape with a smaller planar area than the wiring substrate 20 in plan view as shown in FIG. 1. Therefore, the semiconductor chip 10 has four sides is in plan view. In the example shown in FIG. 1, the semiconductor chip 10 is mounted in the center of the upper surface 20t of the wiring substrate 20, and each of the four sides is of the semiconductor chip 10 extends along each of the four sides 20s of the wiring substrate 20.

On the front surface 1t of the semiconductor chip 10, the plurality of electrodes (pads, electrode pads, bonding pads) 1PD are formed. In the example shown in FIG. 3, the semiconductor chip 10 is mounted on the wiring substrate 20 with the front surface it facing the upper surface 20t of the wiring substrate 20. This mounting method is called a face-down mounting method or a flip-chip connection method.

On the main surface of the semiconductor chip 10 (specifically, the semiconductor element forming area provided on the element forming surface of the semiconductor substrate which is the base material of the semiconductor chip 10), a plurality of semiconductor elements (circuit elements) are formed. The plurality of electrodes 1PD is electrically connected with these semiconductor elements via a wiring (not shown) formed in the wiring layer located inside the semiconductor chip 10 (specifically, between the front surface 1t and the unillustrated semiconductor element forming area).

The semiconductor substrate provided in the semiconductor chip 10 is made of silicon (Si), for example. On the front surface it of the semiconductor chip 10, an insulating film covering the semiconductor substrate and wiring is formed, and a part of each of the plurality of electrodes 1PD (see FIG. 3) is exposed from the insulating film at an opening formed in the insulating film. Also, each of the plurality of electrodes 1PD is made of a metal film. The detailed structure of the semiconductor chip 10 will be described later.

As shown in FIG. 3, each of the plurality of electrodes 1PD is connected to the protruding electrode 1BP, and the plurality of electrodes 1PD of the semiconductor chip 10 and the plurality of terminals 2PD of the wiring substrate 20 are electrically connected with each other via the plurality of protruding electrodes 1BP. The protruding electrode (bump electrode) 1BP is a metal member (conductive member) formed to protrude on the front surface it of the semiconductor chip 10.

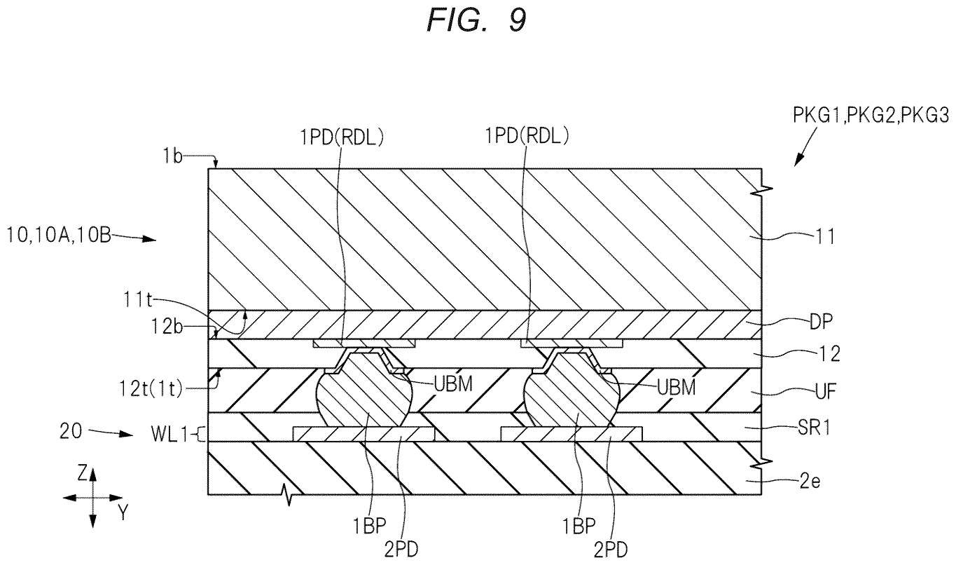

In the present embodiment, the protruding electrode 1BP is made of solder material. The protruding electrode 1BP made of solder material is called a solder bump. The electrode 1PD is electrically connected to the protruding electrode 1BP via an under bump metal (UBM) (see FIG. 9 described later) which is a base metal film of the solder bump which is the protruding electrode 1BP. As the solder material constituting the protruding electrode 1BP, a lead-containing solder material or lead-free solder can be used, as in the case of the solder ball SB described above.

When mounting the semiconductor chip 10 on the wiring substrate 20, solder bumps are formed in advance on both the plurality of electrodes 1PD and the plurality of terminals 2PD, and by applying a heat treatment (reflow process) in a state where the solder bumps are in contact with each other, the solder bumps are integrated to form the protruding electrodes 1BP.

As shown in FIG. 3, the underfill (insulating layer, insulating resin, insulating material) UF is arranged between the semiconductor chip 10 and the wiring substrate 20. The underfill layer UF is arranged to block the space between the front surface it of the semiconductor chip 10 and the upper surface 20t of the wiring substrate 20. Each of the plurality of protruding electrodes 1BP is sealed by the underfill layer UF. The underfill layer UF is made of an insulating (non-conductive) material (for example, a resin material) and is arranged to seal the electrical connection parts (bonding portions of the plurality of protruding electrodes 1BP) between the semiconductor chip 10 and the wiring substrate 20.

In this way, by sealing the joint parts between the plurality of protruding electrodes 1BP and the plurality of terminals 2PD with the underfill layer UF, it is possible to alleviate the stress generated in the electrical connection parts between the semiconductor chip 10 and the wiring substrate 20. The underfill layer UF can alleviate the stress generated at the joint parts between the plurality of electrodes 1PD and the plurality of protruding electrodes 1BP of the semiconductor chip 10. The underfill layer UF can protect the main surface where the semiconductor devices (circuit elements) of the semiconductor chip 10 are formed.

There are various modified examples of the semiconductor device shown in FIGS. 1 to 3. For example, in the example shown in FIG. 3, a single semiconductor chip 10 is mounted on the wiring substrate 20. The number of semiconductor chips 10 mounted on the wiring substrate 20 is not limited to one, and there may be two or more. Also, in the examples shown in FIGS. 1 and 3, the back surface 1b of the semiconductor chip 10 is exposed. As a modified example for FIGS. 1 and 3, there may be a case where a cover member functioning as a heat radiating member is attached to the back surface 1b of the semiconductor chip 10. In this case, it is possible to improve the heat dissipation characteristics of the semiconductor device PKG1. If the semiconductor chip 10 is covered by the cover member, it is possible to protect the semiconductor chip 10.

### <Example of Circuit Configuration>

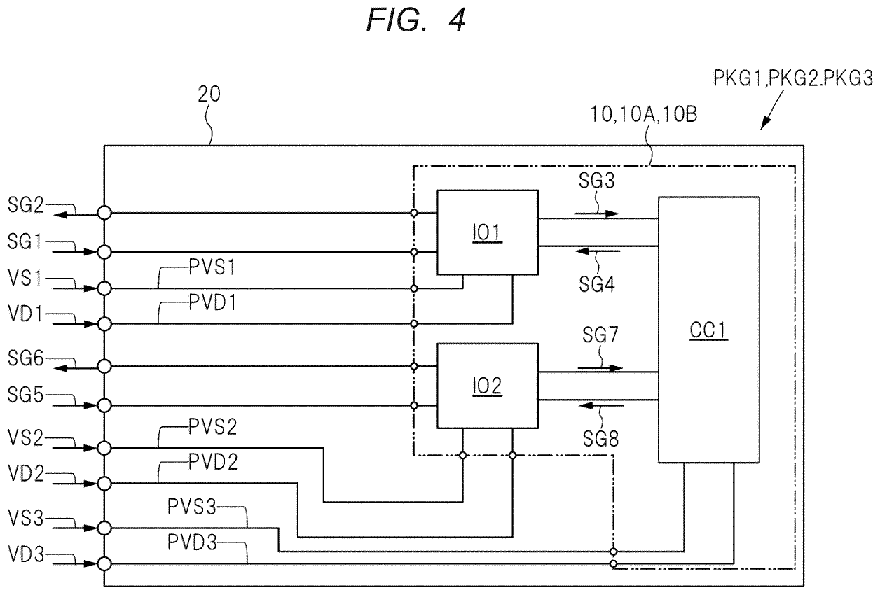

Next, an example of the circuit configuration provided in the semiconductor device PKG1 shown in FIGS. 1 to 3 will be described. FIG. 4 is an explanatory diagram showing an example of the configuration of a circuit provided in the semiconductor device shown in FIGS. 1 to 3. In FIG. 4, multiple circuits, multiple signal transmission paths, and multiple power supply paths provided in the semiconductor device PKG1 are partially illustratively shown.

As shown in FIG. 4, the semiconductor chip 10 of the semiconductor device PKG1 of the present embodiment has an input/output circuit IO1. In the example shown in FIG. 4, the semiconductor chip 10 has an input/output circuit IO1 and a core circuit CC1 electrically coupled with the input/output circuit IO1.

The input/output circuit IO1 includes, for example, a SerDes (Serializer Deserializer) circuit equipped with a function to convert a parallel signal and a serial signal to each other. In other words, the SerDes circuit included in the input/output circuit IO1 is a circuit capable of converting from a serial signal to a parallel signal and from a parallel signal to a serial signal.

In the example shown in FIG. 4, the signal SG1 input to the input/output circuit IO1 through the wiring substrate 20 from the outside is, for example, a serial signal. Also, the signal SG2 output from the input/output circuit IO1 to the outside through the wiring substrate 20 is, for example, a serial signal. On the other hand, the signals SG3 and SG4 transmitted between the input/output circuit IO1 and the core circuit CC1 are, for example, parallel signals. Since the semiconductor chip 10 is equipped with an input/output circuit IO1 including a SerDes circuit, it can adopt different transmission methods in signal transmission inside the semiconductor chip 10 and signal transmission between the semiconductor chip 10 and external devices.

Also, in the example shown in FIG. 4, the semiconductor chip 10 has an input/output circuit IO2. The input/output circuit IO2 and the core circuit CC1 are electrically connected. The input/output circuit IO2 is, for example, an interface circuit for DDR (Double Data Rate) memory. A signal SG5 is input to the input/output circuit IO2 from the outside through the wiring substrate 20. Also, the input/output circuit IO2 outputs a signal SG6, and the signal SG5 is transmitted to an external memory (not shown) through the wiring substrate 20.

The core circuit CC1 performs data processing (for example, arithmetic processing) on the signal SG3 transmitted from the input/output circuit IO1 and outputs a signal SG4. The signal SG4 is converted to the signal SG2 in the input/output circuit IO1 and transmitted to an external device. Similarly, the core circuit CC1 performs data processing (for example, arithmetic processing) on the signal SG7 transmitted from the input/output circuit IO2 and outputs a signal SG8. The signal SG8 is transmitted to the input/output circuit IO2. In FIG. 4, the signal SG6 output by the input/output circuit IO2 and the signal SG8 output by the core circuit CC1 are distinguished. However, the signal SG6 and the signal SG8 may be the same signal.

In the example shown in FIG. 4, each of the input/output circuits IO1 and IO2 is coupled with the same core circuit CC1. However, the number of core circuits CC1 provided in the semiconductor chip 10 is not limited to one, and there may be a plurality of core circuits CC1. Also, the input/output circuits IO1 and IO2 may each be coupled with a different core circuit CC1.

The semiconductor device PKG1 has a path for supplying a voltage to drive the plurality of circuits (input/output circuit IO1, input/output circuit IO2, and core circuit CC1) provided in the semiconductor chip 10.

Specifically, the semiconductor device PKG1 has a power-supply potential supply path PVD1 for supplying a power-supply potential VD1 to the input/output circuit IO1, and a reference potential supply path PVS1 for supplying a reference potential VS1 to the input/output circuit IO1.

The semiconductor device PKG1 has a power-supply potential supply path PVD2 for supplying a power-supply potential VD2 to the input/output circuit IO2, and a reference potential supply path PVS2 for supplying a reference potential VS2 to the input/output circuit IO2.

The semiconductor device PKG1 has a power-supply potential supply path PVD3 for supplying a power-supply potential VD3 to the core circuit CC1, and a reference potential supply path PVS3 for supplying a reference potential VS3 to the core circuit CC1.

In the case of FIG. 4, an example is shown in which different potentials are supplied to the input/output circuit IO1, input/output circuit IO2, and core circuit CC1. However, it is not limited to the case where the potentials to be supplied to the plurality of circuits are different from each other. For example, some or all of the power-supply potentials VD1, VD2, and VD3 may be the same potential. Similarly, some or all of the reference potentials VS1, VS2, and VS3 may be the same potential.

Note that each of the reference potentials VS1, VS2, and VS3 is a potential different from the power-supply potentials VD1, VD2, and VD3, but may be a potential other than the ground potential.

### <Electrode Layout of Semiconductor Chip>

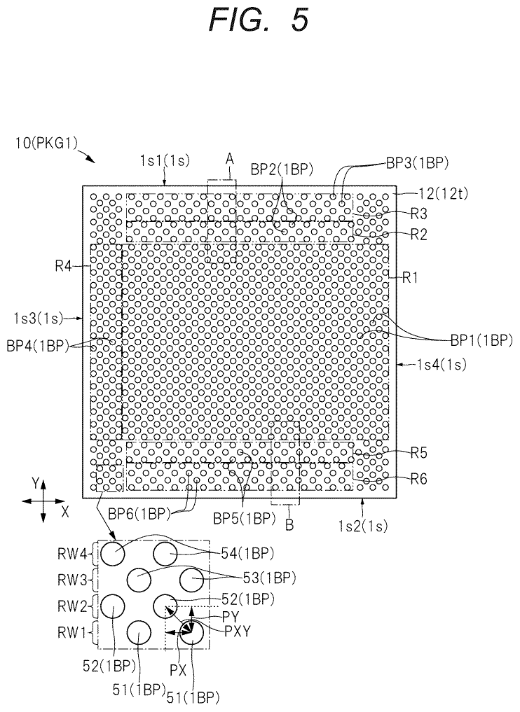

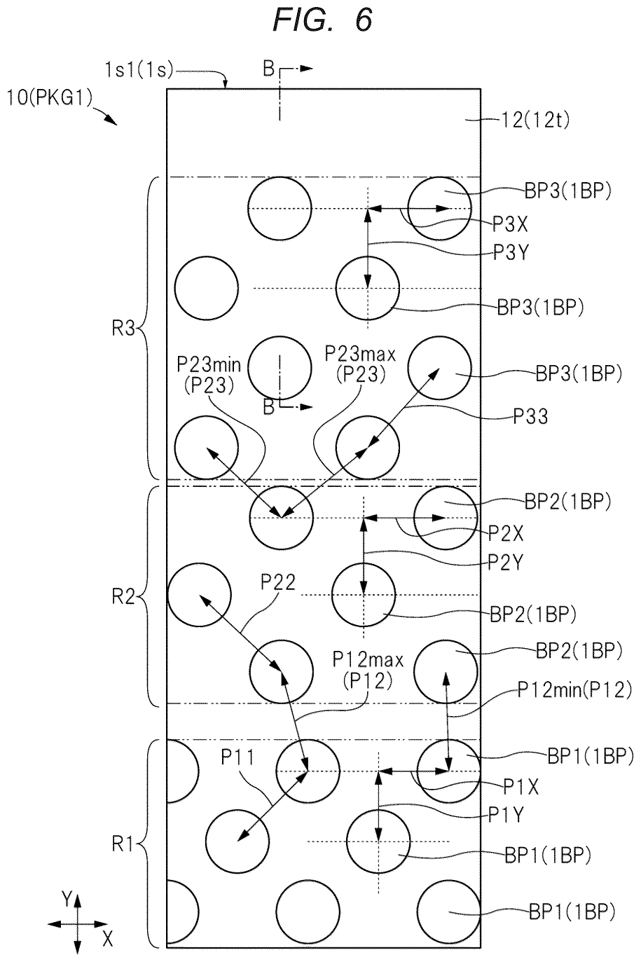

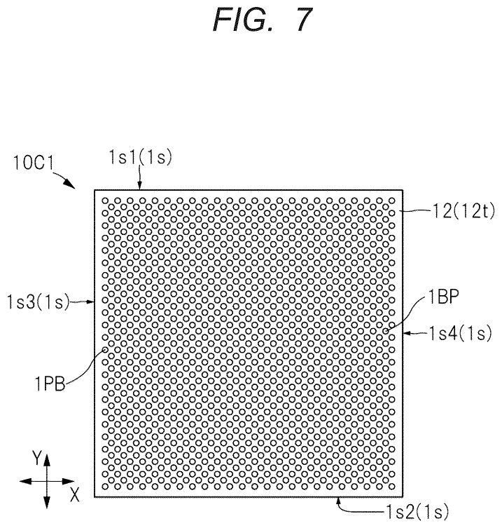

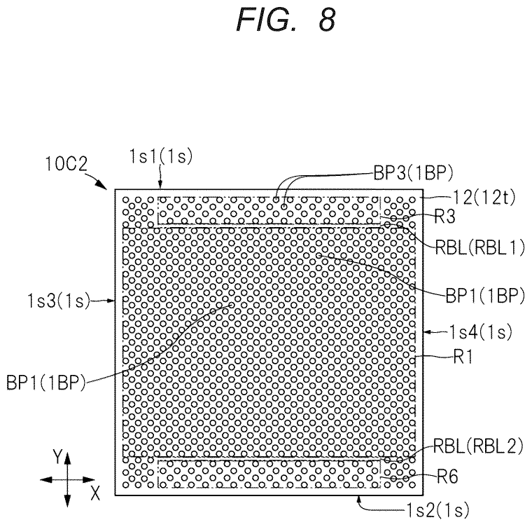

Next, the electrode layout of the semiconductor chip will be described. FIG. 5 is a plan view of an electrode arrangement surface of the semiconductor chip shown in FIG. 3. FIG. 6 is an enlarged plan view at a part A shown in FIG. 5. FIGS. 7 and 8 are a plan view showing an examined example in relation to a layout of the plurality of protruding electrodes shown in FIG. 5. FIG. 9 is an enlarged cross-sectional view along a line B-B shown in FIG. 6.

Generally, the electrodes of the semiconductor chip are not arranged in the central region (including the center) of the semiconductor chip in plan view, but are arranged in the peripheral region surrounding the central region. With the demand for miniaturization (reduction in plan size) of the semiconductor chip, there is a tendency for the electrode arrangement space to be insufficient when the electrodes are arranged only in the peripheral region.

Therefore, as shown in FIGS. 5 to 8, an area array method of regularly arranging electrodes over the entire main surface of the semiconductor chip, including the central region and the peripheral region, is being considered. The central region of the semiconductor chip is an area where major circuits such as core circuits are arranged and is called an active area. Therefore, the electrode arrangement method by the area array method may be called PAA (Pad on Active Area).

From the viewpoint of maximizing the arrangement density of the electrodes, it is preferable that all the protruding electrodes 1BP is arranged at the minimum allowable pitch, as in the semiconductor chip 10C1 shown in FIG. 7. However, due to various circumstances, there may be cases where it is difficult to arrange all the protruding electrodes 1BP at the same pitch as each other.

For example, when a component such as a coil or a capacitor is arranged in a part of the semiconductor chip 10, there may be a region where it is difficult to arrange the protruding electrode 1BP around the component, and the pitch of some of the protruding electrodes 1BP may be different from the pitch of other protruding electrodes 1BP.

Alternatively, if some of the plurality of circuits (input/output circuit IO1, input/output circuit IO2, and core circuit CC1 shown in FIG. 4) that the semiconductor chip 10 has are standardized circuits, the layout of the protruding electrodes 1BP may be defined by the standard. A standardized circuit refers to a circuit block whose specifications and the specifications of the circuit components constituting the circuit have been standardized to enhance the versatility of a circuit with a certain function. Such a circuit block may be referred to as an IP (Intellectual Property) circuit. For example, the input/output circuit IO1 shown in FIG. 4 is standardized, including the arrangement method of protruding electrodes in the circuit block specifications.

Since the circuit scale of the integrated circuit is large, it takes a considerable amount of time to design all circuit blocks from the beginning. By including standardized circuit blocks like IP circuits in part of the integrated circuit, it is possible to improve the efficiency of the design.

Standardized circuits, such as input/output circuit IO1 or input/output circuit IO2, are often interface circuits that transmit signals between other circuits. Interface circuits are often located in the peripheral region of the semiconductor chip. By placing the interface circuit in the peripheral region, the signal transmission path can be shortened.

On the other hand, in the central region, the protruding electrodes 1BP, which mainly supply power potential VD3 (refer to FIG. 4) or reference potential VS3 (refer to FIG. 4) to core circuit CC1 (refer to FIG. 4), are often arranged. The core circuit CC1 formed in the central region transmits signals to external devices via input/output circuit IO1 or input/output circuit IO2.

In cases like the semiconductor chip 10, which includes standardized circuits, it is difficult to arrange all protruding electrodes 1BP at the same pitch as each other. For example, in the case of the semiconductor chip 10C2 shown in FIG. 8, the pitch of some of the protruding electrodes BP3 arranged in the peripheral region is wider than the pitch of the protruding electrodes BP1 arranged in the central region.

### <Definition of Terms Related to Electrode Arrangement>

Hereinafter, the pitch at which the plurality of protruding electrodes 1BP is arranged will be explained. In this specification, terms such as “staggered arrangement”, “pitch”, “component along the X direction of the pitch”, and “component along the Y direction of the pitch” may be used. Each term is defined as follows.

First, a “staggered arrangement” is an arrangement as shown enlarged in FIG. 5. In FIG. 5, if the X direction is defined as the row direction and the Y direction as the column direction, the plurality of protruding electrodes 1BP is arranged as follows.

That is, the plurality of protruding electrodes 1BP is arranged over multiple columns in the Y direction. For example, in FIG. 5, the plurality of protruding electrodes 51 arranged in column RW1, the plurality of protruding electrodes 52 arranged in column RW2 adjacent to column RW1, the plurality of protruding electrodes 53 arranged in column RW3 adjacent to column RW2, and the plurality of protruding electrodes 54 arranged in column RW4 adjacent to column RW3 are shown.

The plurality of protruding electrodes 1BP shown in FIG. 5 is arranged in a staggered manner. Therefore, in the row direction, which is the X direction, the center of each of the plurality of protruding electrodes 52 is located between adjacent protruding electrodes 51 (in the middle in FIG. 5). Similarly, in the X direction, the center of each of the plurality of protruding electrodes 53 is located between adjacent protruding electrodes 52 (in the middle in FIG. 5). In the X direction, the center of each of the plurality of protruding electrodes 54 is located between adjacent protruding electrodes 53 (in the middle in FIG. 5).

On the other hand, in the X direction, the center of each of the plurality of protruding electrodes 53 is located at the same position as the center of each of the plurality of protruding electrodes 51. Similarly, in the X direction, the center of each of the plurality of protruding electrodes 54 is located at the same position as the center of each of the plurality of protruding electrodes 52.

This type of arrangement is called a “staggered arrangement”. Note that an arrangement method in which multiple solder balls SB, as shown in FIG. 1, are arranged in rows and columns along the X and Y directions is called a “matrix arrangement”.

In the case of a staggered arrangement, the spacing between a protruding electrode arranged in a certain row and a protruding electrode arranged in the row next to it can be widened compared to a matrix arrangement, which can improve the arrangement density of the objects to be arranged. Therefore, in the present embodiment, each of the plurality of protruding electrodes 1BP is arranged in a staggered manner in order to improve the arrangement density of the plurality of protruding electrodes 1BP.

However, the arrangement method of the plurality of protruding electrodes 1BP is not limited to a staggered arrangement, and as a modified example, some or all of the plurality of protruding electrodes 1BP may be arranged by a matrix arrangement.

The “pitch” of the protruding electrode 1BP refers to the center-to-center distance between one of the plurality of protruding electrodes 1BP and the protruding electrode 1BP that is located closest to the one. In the example shown in FIG. 5, the center-to-center distance between the protruding electrode 51 and the protruding electrode 52, which is located closest to the protruding electrode 51, is illustrated as pitch PXY.

The “component in the X direction of the pitch” of the protruding electrode 1BP refers to the component in the X direction of the pitch PXY. In the example shown in FIG. 5, the component of the pitch along the X direction between the protruding electrode 51 and the protruding electrode 52 is illustrated as a distance PX.

The “component in the Y direction of the pitch” of the protruding electrode 1BP refers to the component in the Y direction of the pitch PXY. In the example shown in FIG. 5, the component of the pitch along the Y direction between the protruding electrode 51 and the protruding electrode 52 is illustrated as a distance PY.

### <Differences Between Examined Example and Present Embodiment>

Next, the similarities and differences between the semiconductor chip 10 related to the present embodiment shown in FIGS. 5 and 6, and the semiconductor chip 10C2 shown in FIG. 8 will be explained.

As shown in FIG. 9, the semiconductor chip 10 includes a semiconductor substrate 11, a wiring section DP, a wiring layer RDL, an insulating layer 12, and the protruding electrode 1BP. The semiconductor substrate 11 has a surface (main surface) lit. On the surface lit, semiconductor elements such as transistors or diodes (not shown) are formed.

The wiring section DP of the semiconductor chip 10 has a plurality of stacked wiring layers. Except for the wiring layer located in the top layer (the wiring layer furthest from the surface lit) among the plurality of wiring layers and a plug that connects with the semiconductor element, the wiring layers are made of, for example, copper or copper alloy. Between the plurality of wiring layers, an inorganic insulating layer such as silicon oxide is interposed. A pad (not shown) made of, for example, aluminum is formed on the wiring layer located in the top layer of the wiring section DP.

The wiring layer RDL is formed on the surface 11t of the semiconductor substrate 11 (specifically, on the wiring section DP located on the surface 11t). The wiring layer RDL is electrically connected with the semiconductor elements formed on the surface 11t of the semiconductor substrate 11 through the wiring section DP. In FIG. 9, an example of a conductor pattern formed on the wiring layer RDL is illustrated as electrode 1PD. In addition to the electrode 1PD, the wiring layer RDL has wiring patterns connected to the electrode 1PD, and so on.

When distinguishing between the wiring section DP and the wiring layer RDL, the wiring layer RDL may be referred to as a rewiring layer. The wiring layer RDL is made of, for example, copper or copper alloy. The pad formed on the topmost layer of the wiring section DP and the electrode 1PD are electrically connected through the wiring formed on the wiring layer RDL.

The insulating layer 12 has a surface 12b facing the surface lit of the semiconductor substrate 11, and a surface 12t on the opposite side of the surface 12b, and is arranged to cover the wiring layer RDL. The insulating layer 12 has a function of ensuring the electrical insulation of the plurality of protruding electrodes 1BP, and a function as a protective film that protects the wiring layer RDL. From the viewpoint of improving the flatness of the surface 12t of the insulating layer 12, the insulating layer 12 is an organic insulating layer made of, for example, a polyimide resin. However, as a modified example, there may be a case where the insulating layer 12 is an inorganic insulating layer.

A plurality of openings are formed in the insulating layer 12. Each of the plurality of electrodes 1PD provided on the wiring layer RDL is located at a position overlapping any of the plurality of openings formed in the insulating layer 12. Each of the plurality of electrodes 1PD is exposed from the insulating layer 12 at a position overlapping the opening. In the opening, an under bump metal (UBM) which is a base metal film of the protruding electrode 1BP, which is a solder bump, is formed. The plurality of protruding electrodes 1BP and the plurality of electrodes 1PD are electrically connected through the base metal film UBM.

The structure of the semiconductor chip 10 explained using FIG. 9 is also the same for the semiconductor chip 10C2 shown in FIG. 8.

As shown in each of FIGS. 5 and 8, the surface 12t of the insulating layer 12 has a side 1s1 extending in the X direction, a side 1s2 located on the opposite side of the side 1s1, a side 1s3 extending in the Y direction intersecting the X direction, and a side 1s4 located on the opposite side of the side 1s3.

In the case of the semiconductor chip 10 shown in FIG. 5, the surface 12t of the insulating layer 12 includes a region R1 located between the side 1s1 and the side 1s2, a region R2 located between the side 1s1 and the region R1 and located next to the region R1, and a region R3 between the side 1s1 and the region R2 and located next to the region R2.

As shown in FIG. 6, the plurality of protruding electrodes 1BP includes a plurality of protruding electrodes BP1 arranged at positions overlapping the region R1, a plurality of protruding electrodes BP2 arranged at positions overlapping the region R2, and a plurality of protruding electrodes BP3 arranged at positions overlapping the region R3.

Each of the plurality of protruding electrodes BP3 is electrically connected with the input/output circuit IO1 of the semiconductor chip 10 shown in FIG. 4. Each of the plurality of protruding electrodes BP1 and BP2 shown in FIG. 6 is electrically connected with a circuit (for example, the core circuit CC1) different from the input/output circuit IO1 shown in FIG. 4.

As shown in FIG. 6, the plurality of protruding electrodes BP1 are arranged at a pitch P11. The plurality of protruding electrodes BP2 are arranged at a pitch P22 wider than the pitch P11. The plurality of protruding electrodes BP3 are arranged at a pitch different from each of the pitches P11 and P22. In the Y direction perpendicular to the X direction, the component (distance P2Y) in the Y direction of the pitch P22 is larger than the component (distance P1Y) in the Y direction of the pitch P11.

On the other hand, in the case of the semiconductor chip 10C2 shown in FIG. 8, a blank region RBL where the protruding electrode 1BP is not arranged is provided between the region R1 and the region R3. In this respect, the semiconductor chip 10 shown in FIG. 5 differs from the semiconductor chip 10C2 shown in FIG. 8.

According to the study by the present inventors, it has been found that in the case of a semiconductor device using the semiconductor chip 10C2 shown in FIG. 8, a void may be formed between the insulating layer 12 and the underfill layer UF shown in FIG. 9. It has been found that the void is likely to occur in the vicinity of the blank region RBL shown in FIG. 8.

According to the study by the present inventors, the cause of the void is presumed to be as follows. The manufacturing process of the semiconductor device includes a washing process for washing the residue left around the plurality of protruding electrodes 1BP after mounting the semiconductor chip 10 on the wiring substrate 20 with a washing liquid, and a drying process for removing the washing liquid. In the drying process, it is preferable that all moisture is removed, but it has been found that in the vicinity of the blank region RBL shown in FIG. 8, some moisture is difficult to remove and washing residue is likely to occur. The washing residue is likely to occur in the gap between the protruding electrode 1BP and the insulating layer 12 shown in FIG. 9.

The void is due to this washing residue, and it is considered that the washing residue (i.e., the void) generated in the gap between the protruding electrode 1BP and the insulating layer 12 reduces the adhesion between the underfill layer UF (see FIG. 3) and the insulating layer 12. In the blank region RBL of the semiconductor chip 10C2 shown in FIG. 8, the distance between the region R1 where the plurality of protruding electrodes BP1 are arranged and the region R3 where the plurality of protruding electrodes BP3 are arranged is wider compared to the pitch of the plurality of protruding electrodes BP1 and the pitch of the plurality of protruding electrodes BP3.

There is no particular problem when the volume of the void is small, but when the volume of the void is large, there is a possibility that the adjacent protruding electrodes 1BP may short-circuit. Therefore, if the residual moisture that causes the void can be suppressed, the reliability of the semiconductor device can be improved.

In the case of the semiconductor chip 10 according to the present embodiment shown in FIG. 6, the region R2 where a plurality of protruding electrodes BP2 are arranged is provided between the region R1 where the plurality of protruding electrodes BP1 are arranged and the region R3 where a plurality of protruding electrodes BP3 are arranged. In the case of the semiconductor chip 10, by adjusting the pitch P22 of the plurality of protruding electrodes BP2 arranged in the region R2, it is possible to reduce the area of the gap where the protruding electrode 1BP is not arranged. Therefore, in the case of a semiconductor device PKG1 (see FIG. 3) using the semiconductor chip 10, the occurrence of voids can be suppressed, thereby improving reliability.

In the following description, the protruding electrode 1BP, which is arranged to reduce the wide gap that occurs between the protruding electrode BP3 arranged in the region R3 and the protruding electrode BP1 arranged in the region R1, like the protruding electrode BP2, may be referred to as the array adjustment protruding electrode 1BP.

As shown in FIGS. 5 and 6, a plurality of protruding electrodes BP3 are arranged in the peripheral region of the semiconductor chip 10. In other words, among the plurality of protruding electrodes 1BP, the plurality of protruding electrodes BP3 include the protruding electrode 1BP arranged at the position closest to the side 1s1. Since the plurality of protruding electrodes BP3 are arranged in the peripheral region of the semiconductor chip 10, even if moisture accumulates between the protruding electrode BP3 and the insulating layer 12, the moisture can be easily removed by the drying process.

The pitch P33 shown in FIG. 6 is different from the pitch P11 and the pitch P22. For example, in the example shown in FIG. 6, the pitch P33 is even wider than the pitch P22. However, as a modified example, there may be a case where the pitch P33 is narrower than the pitch P22.

As described above, the circuit to which each of the plurality of protruding electrodes BP3 is electrically connected is the input/output circuit IO1 (see FIG. 4). Therefore, by arranging the plurality of protruding electrodes BP3 in the peripheral region of the semiconductor chip 10, the path length of the signal transmission path can be shortened.

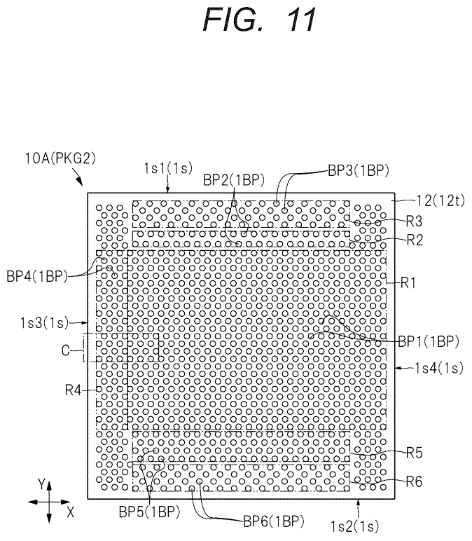

In the example shown in FIG. 6, the plurality of protruding electrodes BP2 are arranged in three rows in the Y direction. The number of rows in the Y direction of the plurality of protruding electrodes BP2 is not limited to three. For example, in the case of the semiconductor chip 10A shown in FIG. 11, which will be described later as a modified example, the plurality of protruding electrodes BP2 arranged in the region R2 are arranged in two rows in the Y direction. Also, the plurality of protruding electrodes BP5 arranged in a region R5 are arranged in four rows in the Y direction. Although not shown, as a further modified example, there may be a case where the plurality of protruding electrodes BP2 or the plurality of protruding electrodes BP5 are arranged in five or more rows in the Y direction.

However, in the case of the present embodiment, the area of the gap is reduced by adjusting the component in the Y direction of the pitch P22. Therefore, it is preferable that the number of rows in the Y direction of the plurality of protruding electrodes BP2 is two or more. Also, if the number of rows in the Y direction of the plurality of protruding electrodes BP2 becomes extremely large, the area of the region R1 where the plurality of protruding electrodes BP1 are arranged is reduced. From the viewpoint of improving the arrangement density of the protruding electrode 1BP, it is preferable that the area of the region R1 is large. Therefore, it is preferable that the number of rows in the Y direction of the plurality of protruding electrodes BP2 is, for example, five or less.

Also, in the case of the present embodiment, strictly speaking, the area of the gap is reduced by adjusting the component in the Y direction of the pitch P22. Therefore, at least, if the component (distance P2Y) in the Y direction of the pitch P22 is longer than the component (distance P1Y) in the Y direction of the pitch P11, the value of the component (distance P2X) in the X direction of the pitch P22 can be set arbitrarily. In the example shown in FIG. 6, the pitch P22 is wider than the pitch P11. However, as a modified example, depending on the value of the component (distance P2X) in the X direction of the pitch P22, there may be a case where the pitch P22 is the same as the pitch P11, or the pitch P22 is narrower than the pitch P11. From the perspective of ease of adjustment for filling the area of the gap, it is preferable that the component (distance P2X) in the X direction of the pitch P22 is wide. Therefore, as shown in FIG. 6, it is easier to adjust to fill the gap when the pitch P22 is wider than pitch P11.

As shown in FIG. 6, each of the plurality of protruding electrodes BP1 and the plurality of protruding electrodes BP2 are arranged in a staggered manner. From the perspective of improving the arrangement density of the protruding electrode 1BP, it is preferable that they are arranged in a staggered manner as in the present embodiment.

In the example shown in FIG. 6, the component (distance P1X) in the X direction of the pitch P11 and the component (distance P1Y) in the Y direction of the pitch P11 are equal to each other. The component (distance P2X) in the X direction of the pitch P22 and the component (distance P2Y) in the Y direction of the pitch P22 are equal to each other. The component (distance P3X) in the X direction of the pitch P33 and the component (distance P3Y) in the Y direction of the pitch P33 are equal to each other.

In the example shown in FIG. 6, the minimum pitch (pitch P12min) between one of the plurality of protruding electrodes BP1 and one of the plurality of protruding electrodes BP2 is equal to or greater than the pitch P11. Also, the minimum pitch (pitch P23min) between one of the plurality of protruding electrodes BP3 and one of the plurality of protruding electrodes BP2 is equal to or greater than the pitch P11. The pitch P12min shown in FIG. 6 is the minimum value of the pitch between one of the plurality of protruding electrodes BP1 and one, which is located next to the one of the plurality of protruding electrodes BP1, of the plurality of protruding electrodes BP2. Similarly, the pitch P23min shown in FIG. 6 is the minimum value of the pitch between one of the plurality of protruding electrodes BP3 and one, which is located next to the one of plurality of protruding electrodes BP3, of the plurality of protruding electrodes BP2.

In the case of the present embodiment, the pitch P11 of the plurality of protruding electrodes BP1 is set to a value that is acceptable from the perspective of preventing short-circuiting of adjacent protruding electrodes BP1. Therefore, by each of the pitch P12 and the pitch P23 being equal to or greater than the pitch P11, it is possible to prevent a short circuit between the protruding electrode BP1 and the protruding electrode BP2, or between the protruding electrode BP3 and the protruding electrode BP2.

In the example shown in FIG. 6, the ball diameter (maximum value of the diameter in plan view) of each of the plurality of protruding electrodes 1BP is about 100 μm.

Each of the distances P1X and P1Y shown in FIG. 6 is 92 μm. Therefore, the pitch P11 is 130 μm. Each of the distances P2X and P2Y shown in FIG. 6 is 104 μm. Therefore, the pitch P22 is 147 μm. Also, the pitch P12min shown in FIG. 6 is equal to pitch P11. The pitch P23min is wider than the pitch P11 and is 134 μm.

On the other hand, it is preferable that the maximum value of the pitch (pitch P12max in FIG. 6) between one of the plurality of protruding electrodes BP1 and the protruding electrode BP2 located next to the one protruding electrode BP1 is equal to or less than the pitch P22. Also, it is preferable that the maximum value of the pitch (pitch P23max in FIG. 6) between one of the plurality of protruding electrodes BP3 and the protruding electrode BP2 located next to the one protruding electrode BP3 is equal to or less than the pitch P22.

The pitch P12max shown in FIG. 6 is 135 μm, and the pitch P23max is 144 μm. As a modified example for FIG. 6, there may be a case where one or both of the pitch P12max and the pitch P23max are narrower than the pitch P22. Even in this case, if the average value of the center-to-center distance between the protruding electrode BP1 and the protruding electrode BP2 is equal to or less than the pitch P22, it is possible to suppress the residual moisture.

From the perspective of ease of adjustment of the values of the pitch P12min, the pitch P12max, the pitch P23min, and the pitch P23max, it is preferable that the value of the pitch P22 is larger within the range where no residual moisture occurs. Therefore, by each of the pitch P12 and the pitch P23 being equal to or less than the pitch P22, it is possible to prevent moisture from remaining between the region R1 and the region R2, and between the region R2 and the region R3.

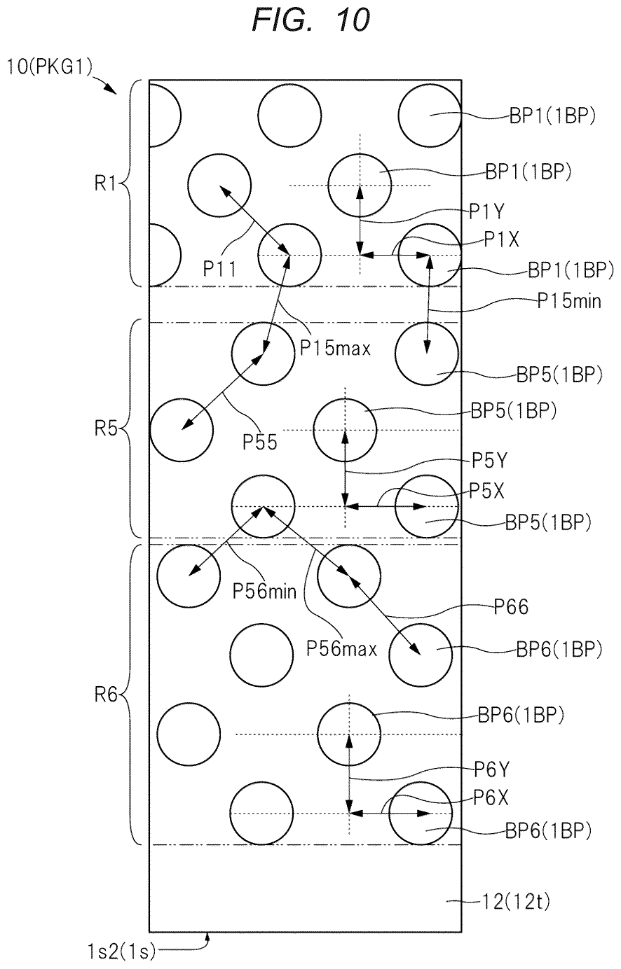

By the way, using FIG. 6, the layout of the protruding electrode 1BP around the side 1s1 of the semiconductor chip 10 shown in FIG. 5 was explained. In the case of the semiconductor chip 10, as shown in FIG. 5, the layout around the side 1s2 of the semiconductor chip 10 is the same as that around the side 1s1. FIG. 10 is an enlarged plan view at a part B shown in FIG. 5.

As shown in FIG. 10, the plurality of protruding electrodes 1BP includes, in a plan view, a plurality of protruding electrodes BP1 arranged at positions overlapping the region R1, a plurality of protruding electrodes BP5 arranged at positions overlapping the region R5, and a plurality of protruding electrodes BP6 arranged at positions overlapping a region R6.

Each of the plurality of protruding electrodes BP6 is electrically connected with the input/output circuit IO1 of the semiconductor chip 10 shown in FIG. 4. Each of the plurality of protruding electrodes BP1 and BP5 shown in FIG. 10 is electrically connected with a circuit (for example, the core circuit CC1) different from the input/output circuit IO1 shown in FIG. 4.

As shown in FIG. 10, the plurality of protruding electrodes BP1 is arranged at a pitch P11. The plurality of protruding electrodes BP5 is arranged at a pitch P55, which is wider than the pitch P11. The plurality of protruding electrodes BP6 is arranged at a pitch different from both the pitch P11 and the pitch P55. In the Y direction perpendicular to the X direction, the component (distance P5Y) in the Y direction of the pitch P55 is larger than the component (distance P1Y) in the Y direction of pitch P11.

As explained with reference to FIG. 6, the relationship between the pitch P11 and the pitch P22, if the component (distance PSY) in the Y direction of the pitch P55 shown in FIG. 10 is longer than the component (distance P1Y) in the Y direction of the pitch P11, the value of the component (distance P5X) in the X direction of the pitch P55 can be set arbitrarily. In the example shown in FIG. 10, the pitch P55 is wider than the pitch P11. However, as a modified example, depending on the value of the component (distance PSX) in the X direction of the pitch P55, the pitch P55 may be the same as the pitch P11, or the pitch P55 may be narrower than the pitch P11. As shown in FIG. 10, it is easier to adjust to fill the gap when the pitch P55 is wider than the pitch P11.

According to the study by the present inventors, it was found that the degree of residual moisture in the drying process varies depending on the drying method. That is, in the drying process, there may be a case where it is dried by blowing air in one direction. In this case, the degree of moisture removal varies depending on the direction of the wind for drying.

For example, in the case of the semiconductor chip 10C2 shown in FIG. 8, when air is blown along the Y direction from the side 1s2 to the side 1s1, moisture tends to remain around the blank region RBL1, which is relatively close to edge 1s1, among the two blank regions RBL. On the other hand, moisture is less likely to remain around the blank region RBL2, which is relatively close to the side 1s2. As a result, voids are less likely to occur around the blank region RBL2.

Considering this finding, as a modified example for the semiconductor chip 10 shown in FIG. 5, it is conceivable that the structure around the side 1s2 is the same as that of the semiconductor chip 10C2 shown in FIG. 8. In this case, even if there is a region corresponding to the blank region RBL2 shown in FIG. 8, voids due to residual moisture are less likely to occur by blowing air along the Y direction from the side 1s2 to the side 1s1 in the drying process.

On the other hand, in the case of the semiconductor chip 10 shown in FIG. 5, as described above, the structure around the side 1s2 and the structure around the side 1s1 are similar to each other. Therefore, in the case of the semiconductor chip 10, voids can be suppressed regardless of the drying method.

It is preferable that the layout of the protruding electrodes BP5 and BP6 shown in FIG. 10 is the same as the layout of the protruding electrodes BP2 and BP3 explained using FIG. 6.

As shown in FIGS. 5 and 10, the plurality of protruding electrodes BP6 arranged in the region R6 is arranged in the peripheral region of the semiconductor chip 10. In other words, among the plurality of protruding electrodes 1BP, the plurality of protruding electrodes BP6 includes the protruding electrodes 1BP arranged at the position closest to the side 1s2.

The pitch P66 shown in FIG. 10 is different from the pitch P11 and the pitch P55. For example, in the example shown in FIG. 10, the pitch P66 is even wider than the pitch P55. However, as a modified example, there may be cases where the pitch P66 is narrower than the pitch P55.

The circuit with which each of the plurality of protruding electrodes BP6 is electrically connected is the input/output circuit IO1 (refer to FIG. 4). Therefore, by arranging the plurality of protruding electrodes BP6 in the peripheral region of the semiconductor chip 10, the path length of the signal transmission path can be shortened.

In the example shown in FIG. 10, the plurality of protruding electrodes BP5 is arranged in three rows in the Y direction. The number of rows in the Y direction of the plurality of protruding electrodes BP5 is not limited to three rows, and there may be, for example, two rows or four or more rows.

As shown in FIG. 10, each of the plurality of protruding electrodes BP1 and the plurality of protruding electrodes BP5 is arranged in a staggered manner. In the example shown in FIG. 10, the component (distance P5X) in the X direction of the pitch P55 and the component (distance P5Y) in the Y direction of the pitch P55 are equal to each other. The component (distance P6X) in the X direction of the pitch P66 and the component (distance P6Y) in the Y direction of the pitch P66 are equal to each other.

In the example shown in FIG. 10, the minimum pitch (pitch P15min) between one of the plurality of protruding electrodes BP1 and one of the plurality of protruding electrodes BP5 is equal to or greater than the pitch P11. Also, the minimum pitch (pitch P56min) between one of the plurality of protruding electrodes BP6 and one of the plurality of protruding electrodes BP5 is equal to or greater than the pitch P11. The pitch P15min shown in FIG. 10 is the minimum value of the pitch between one of the plurality of protruding electrodes BP1 and one, which is located next to the one of the plurality of protruding electrodes BP1, of the plurality of protruding electrode BP5. Similarly, the pitch P56min shown in FIG. 10 is the minimum value of the pitch between one of the plurality of protruding electrodes BP6 and one, which is located next to the one of the plurality of protruding electrodes BP6, of the plurality of protruding electrode BP5.

On the other hand, the maximum value of the pitch (pitch P15max in FIG. 10) between one of the plurality of protruding electrodes BP1 and one, which is located next to the one of the plurality of protruding electrodes BP1, of the plurality of protruding electrode BP5 is equal to or less than the pitch P55. Also, the maximum value of the pitch (pitch P56max in FIG. 10) between one of the plurality of protruding electrodes BP6 and one, which is located next to the one of the plurality of protruding electrodes BP6, of the plurality of protruding electrodes BP5 is equal to or less than the pitch P55.

### First Modified Example

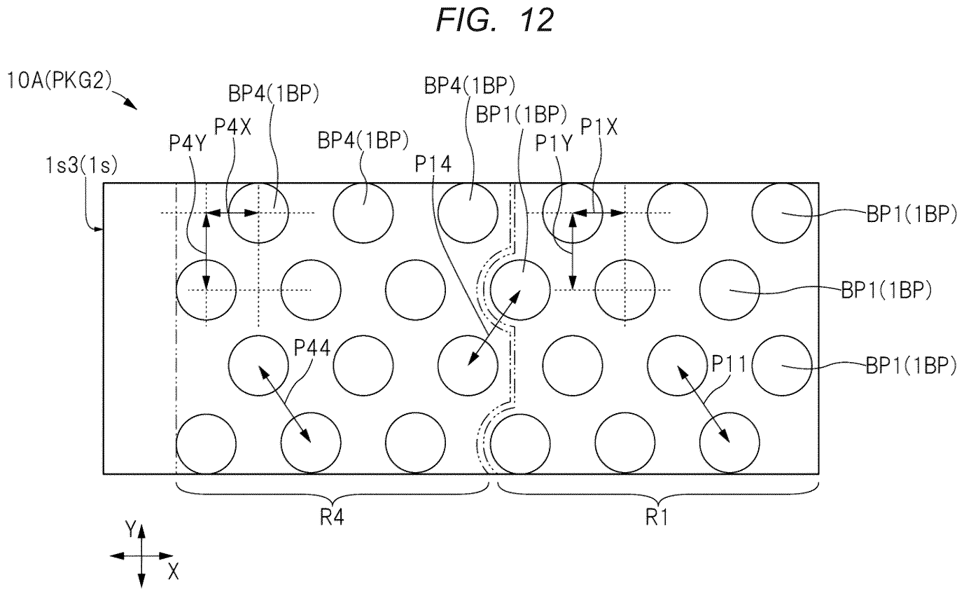

Next, a modified example for the semiconductor chip 10 shown in FIG. 5 will be described. FIG. 11 is a plan view of an electrode arrangement surface of the semiconductor chip, which is a modified example in relation to FIG. 5. FIG. 12 is an enlarged plan view at a part C shown in FIG. 11.

In FIGS. 11 and 12, as a modified example in relation to the semiconductor device PKG1 having the semiconductor chip 10 shown in FIGS. 5 and 6, the semiconductor device PKG2 having the semiconductor chip 10A is shown. The surface 12t of the insulating layer 12 of the semiconductor chip 10A shown in FIGS. 11 and 12 includes the side 1s3 extending in the Y direction, and a region R4 located between the side 1s3 and the region R1. This point is the same as the semiconductor chip 10 shown in FIG. 5.

The plurality of protruding electrodes 1BP includes a protruding electrode BP4 arranged at a position overlapping the region R4 in plan view. Each of the plurality of protruding electrodes BP4 is electrically connected with a circuit (for example, the input/output circuit IO2 shown in FIG. 4) of the semiconductor chip 10A. Each of the plurality of protruding electrodes BP1 and the plurality of protruding electrodes BP2 (refer to FIG. 11) is electrically connected with a circuit (for example, the core circuit C1 shown in FIG. 4) different from the input/output circuit IO2.

The plurality of protruding electrodes BP4 is arranged at the pitch P44. The value of the pitch P44 and the value of the pitch P11 are the same as each other. That is, they are arranged at the same pitch P11 as the plurality of protruding electrodes BP1. Also, in both the X direction and the Y direction, the plurality of protruding electrodes BP4 is arranged at the same pitch as the plurality of protruding electrodes BP1.

In detail, as shown in FIG. 12, each of the plurality of protruding electrodes BP4 is arranged at the pitch P44. Also, each of the plurality of protruding electrodes BP1 is arranged at the pitch P11. In the case of the semiconductor chip 10A, the distance P4X, which is a component in the X direction of the pitch P44, is equal to the distance P1X, which is a component in the X direction of the pitch P11, and the distance P4Y, which is a component in the Y direction of the pitch P44, is equal to the distance P1Y, which is a component in the Y direction of the pitch P11. Also, the pitch P14 between the protruding electrode BP1 and the protruding electrode BP4, which are adjacent to each other, is equal to each of the pitch P11 and the pitch P44.

As explained using FIG. 8, it is known that voids, which cause a decrease in the reliability of the semiconductor device, are easily formed around the blank area RBL shown in FIG. 8. In this modified example, since the plurality of protruding electrodes BP4 is arranged at the same pitch as plurality of protruding electrodes BP1 in both the X and Y directions, it is possible to prevent gaps where no protruding electrodes are arranged, like the blank area RBL shown in FIG. 8.

Meanwhile, in the case of the semiconductor chip 10 shown in FIG. 5, the circuit with which the plurality of protruding electrodes BP4 is connected is not, for example, an IP circuit, but a circuit newly designed with a layout of at least one protruding electrode 1BP according to the specifications of the semiconductor chip 10. Therefore, in the case of the semiconductor chip 10 shown in FIG. 5, the plurality of protruding electrodes BP4 is arranged at the same pitch P1 (see FIG. 6) as the plurality of protruding electrodes BP1 in both the X and Y directions.

On the other hand, in the case of the semiconductor chip 10A shown in FIGS. 11 and 12, the input/output circuit IO2 (see FIG. 4) with which the plurality of protruding electrodes BP4 is connected is, for example, an interface circuit for DDR memory as mentioned above. Memory interface circuits are often IP circuits because they are often incorporated into various integrated circuits. In this modified example, the input/output circuit IO2 is a standardized IP circuit.

Therefore, in this modified example, in order to arrange the plurality of protruding electrodes BP4 at the same pitch as the plurality of protruding electrodes BP1, it is necessary to align the layout of the plurality of protruding electrodes BP1 with the layout of the plurality of protruding electrodes BP4.

The semiconductor chip 10A of this modified example is designed so that the layout of the plurality of protruding electrodes BP1 is the same as the layout of the plurality of protruding electrodes BP4. Therefore, unlike the case shown in FIG. 6, in this modified example, the values of the distance P1X and the distance P1Y are different.

In the example shown in FIG. 12, the component (distance P1Y) along the Y direction of the pitch P11 is longer than the component (distance PIX) along the X direction of the pitch P11. Also, the component (distance P4Y) along the Y direction of the pitch P44 is longer than the component (distance P4X) along the X direction of the pitch P44.

In the example shown in FIG. 12, each of the distances P1X and P4X is, for example, 75 μm. On the other hand, each of the distances P1Y and P4Y is, for example, 110 μm.

In the case of a memory interface circuit, there are many signal transmission lines (hereinafter referred to as signal lines). Therefore, in the wiring part DP of the semiconductor chip (see FIG. 9) and the wiring layer of the wiring substrate 20 (see FIG. 9), as shown in FIG. 12, there may be cases where one of the values of the distance P1X and the distance P1Y is longer than the other in order to secure space for arranging a large number of signal lines.

On the other hand, the plurality of protruding electrodes BP1 is connected with the power-supply potential supply path PVD3 for supplying the power-supply potential VD3 to the core circuit CC1 shown in FIG. 4, or a reference potential supply path PVS3 for supplying a reference potential VS3 to the core circuit CC1.

In the case of terminals for power supply, such as the protruding electrode BP1, unlike the signal transmission protruding electrode BP4, as shown in FIG. 6, the values of the distance P1X and the distance P1Y are often equal. In the case of this modified example, where the values of the distance P1X and the distance P1Y are different, there are the following advantages.

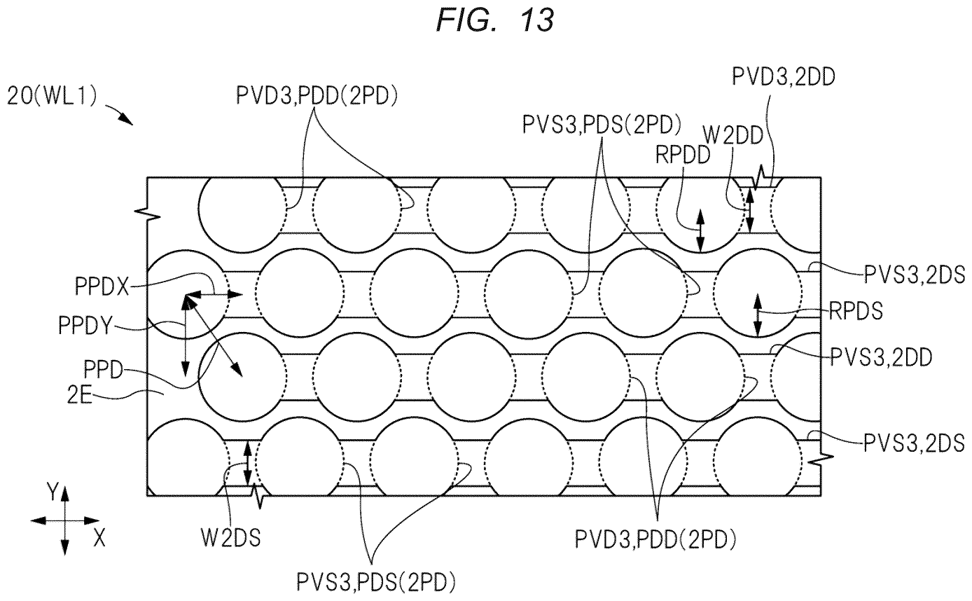

FIG. 13 is an enlarged plan view showing an example of the layout of the topmost wiring layer of a wiring substrate on which the semiconductor chip shown in FIGS. 11 and 12 is mounted.

Each of the plurality of protruding electrodes BP1 shown in FIGS. 11 and 12 is connected with either the power-supply potential supply path PVD3, which supplies a power-supply potential to the core circuit CC1 shown in FIG. 4, or a reference potential supply path PVS3, which supplies a reference potential to the core circuit CC1.

On the wiring layer WL1 of the wiring substrate 20 shown in FIGS. 3 and 13, a plurality of terminals 2PD connected to any of the plurality of protruding electrodes BP1, BP2, and BP3 shown in FIG. 11 is arranged.

In the example shown in FIG. 13, the wiring layer WL1 includes a plurality of power-supply potential terminals PDD, which are electrically connected to the power-supply potential supply path PVD3 among the plurality of terminals 2PD, and a plurality of reference potential terminals PDS, which are electrically connected to the reference potential supply path PVS3 among the plurality of terminals 2PD. The wiring layer WL1 is connected to each of the plurality of power-supply potential terminals PDD, arranged in the X direction and includes a power-supply potential wiring 2DD extending in the X direction. The wiring layer WL1 is connected to each of the plurality of reference potential terminals PDS arranged in the X direction and includes a reference potential wiring 2DS extending in the X direction.

In the Y direction, the plurality of power-supply potential wirings 2DD and the plurality of reference potential wirings 2DS are arranged alternately. The plurality of power-supply potential terminals PDD is electrically connected via the power-supply potential wiring 2DD, thereby stabilizing the potential of the power-supply potential supply path PVD3. Similarly, the plurality of reference potential terminals PDS is electrically connected via the reference potential wiring 2DS, thereby stabilizing the potential of the reference potential supply path PVS3.

The above configuration can be realized even when the value of distance P1X is equal to the value of distance P1X, as explained using the semiconductor chip 10 shown in FIG. 6.

However, in this modified example, as shown in FIG. 12, the value of distance P1Y is larger than the value of distance P1X, so the layout of the plurality of terminals 2PD in the wiring layer WL1 shown in FIG. 13 is as follows. That is, in the Y direction (column direction), the component (distance PPDY) in the Y direction of the pitch PPD of the adjacent terminals 2PD is longer than the component (distance PPDX) in the X direction of the pitch PPD. In the example shown in FIG. 13, the distance PPDX is, for example, 75 μm. On the other hand, the distance PPDY is, for example, 110 μm.

If the values of distance PPDX and distance PPDY shown in FIG. 13 are the same, it is necessary to design the widths of the power-supply potential wiring 2DD and the reference potential wiring 2DS to be narrow in order to prevent short-circuiting between the power-supply potential supply path VDD3 and the reference potential supply path VDS3. On the other hand, as in this modified example, if the distance PPDY is long, the concern of short-circuiting between the power-supply potential supply path VDD3 and the reference potential supply path VDS3 becomes smaller, so the width W2DD of the power-supply potential wiring 2DD shown in FIG. 13 and the width W2DS of the reference potential wiring 2DS can be widened.

For example, in the example shown in FIG. 13, each outer edge of the plurality of power-supply potential terminals PDD forms an arc shape. The width W2DD of the power-supply potential wiring 2DD in the Y direction is equal to or greater than the radius RPDD of the arc of the power-supply potential terminal PDD. By widening the width W2DD of the power-supply potential wiring 2DD, the potential of the power-supply potential supply path PVD3 can be further stabilized.

In the example shown in FIG. 13, each outer edge of the plurality of reference potential terminals PDS forms an arc shape. The width W2DS of the reference potential wiring 2DS in the Y direction is equal to or greater than the radius RPDS of the arc of the reference potential terminal PDS. By widening the width W2DS of the reference potential wiring 2DS, the potential of the reference potential supply path PVS3 can be further stabilized.

The semiconductor chip 10A shown in FIG. 11 differs from the semiconductor chip 10 shown in FIG. 5 in the following points in addition to the above differences. That is, the plurality of protruding electrodes BP2 arranged in the region R2 is arranged in two rows in the Y direction. Also, the plurality of protruding electrodes BP5 arranged in the region R5 is arranged in four rows in the Y direction.

However, the positional relationship between the plurality of protruding electrodes BP2 and the plurality of protruding electrodes BP1, and the positional relationship between the plurality of protruding electrodes BP2 and the plurality of protruding electrodes BP3, are the same as those of the semiconductor chip 10 explained using FIGS. 5 and 6, so the redundant explanation will be omitted. Similarly, the positional relationship between the plurality of protruding electrodes BP5 and the plurality of protruding electrodes BP1, and the positional relationship between the plurality of protruding electrodes BP5 and the plurality of protruding electrodes BP6, are the same as those of the semiconductor chip 10 explained using FIGS. 5 and 10, so the redundant explanation will be omitted.

Also, the semiconductor device PKG2 explained using FIGS. 11 and 12 is the same as the semiconductor device PKG1 shown in FIGS. 5 and 6, except for the differences mentioned above. Therefore, the redundant explanation will be omitted.

### Second Modified Example

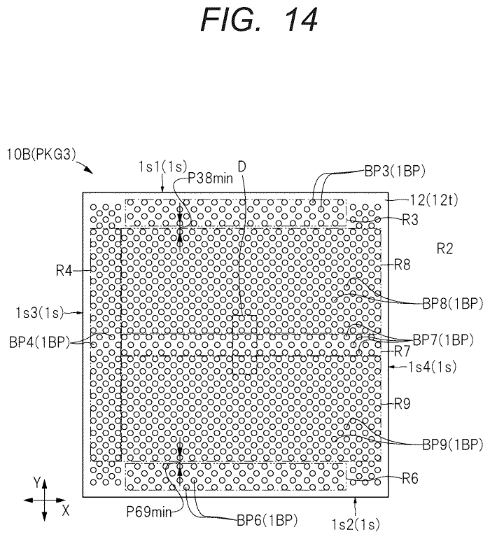

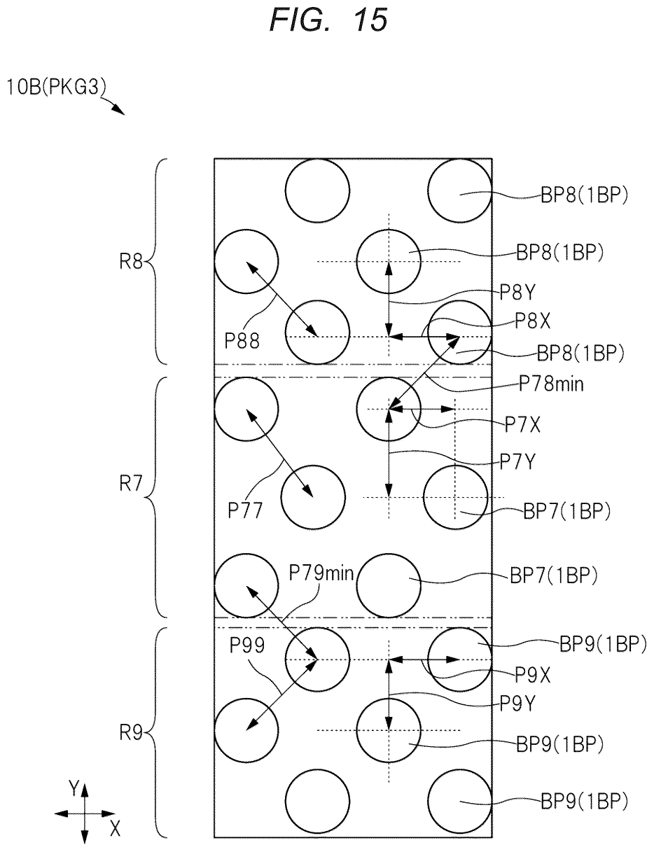

Next, we will explain other modified examples for the semiconductor chip 10 shown in FIG. 5. FIG. 14 is a plan view of the electrode arrangement side of the semiconductor chip of another modified example for FIG. 5. FIG. 15 is an enlarged plan view at a part D shown in FIG. 14.

In the case of the semiconductor device PKG1 shown in FIG. 5 and the semiconductor device PKG2 shown in FIG. 11, the following method was used to prevent a gap from occurring when the pitch between the plurality of protruding electrodes BP3 arranged in the region R3, which is the peripheral region, and the plurality of protruding electrodes BP1 arranged in the region R1, which is the central region, is different. That is, in the case of the semiconductor device PKG1 and the semiconductor device PKG2, the region R2 is provided between the region R3 and the region R1 shown in FIG. 6, and the component (distance P2Y) in the Y direction of the pitch P22 of the plurality of protruding electrodes BP2 arranged in the region R2 is longer than the component (distance P1Y) in the Y direction of the pitch P11 of the plurality of protruding electrodes BP1 arranged in the region R1.

On the other hand, in the case of the semiconductor device PKG3 shown in FIG. 14, it differs from the semiconductor device PKG1 and the semiconductor device PKG2 in that a region R8 corresponding to the region R1 shown in FIG. 5 and the region R3 are adjacent. Also, in the case of the semiconductor device PKG3, it differs from the semiconductor device PKG1 and the semiconductor device PKG2 in the following points. That is, a region R7 is provided between the region R8 corresponding to the region R1 shown in FIG. 5 and a region R9. As shown in FIG. 15, the component (distance P7Y) in the Y direction of a pitch P77 of the plurality of protruding electrodes BP7 arranged in the region R7 is longer than the component (distance P8Y) in the Y direction of a pitch P82 of the plurality of protruding electrodes BP8 arranged in the region R8. The plurality of protruding electrodes BP7 arranged in the region R7 is the protruding electrodes 1BP for adjusting the arrangement to prevent gaps that cause voids from occurring between the region R8 and the region R3.

Hereinafter, the configuration of the semiconductor device PKG3 will be described in detail. The semiconductor device PKG3 has the wiring substrate 20, a semiconductor chip 10B mounted on the wiring substrate 20 via the plurality of protruding electrodes 1BP, and the underfill layer UF that is arranged between the semiconductor chip 10B and the wiring substrate 20 and seals the plurality of protruding electrodes 1BP, as shown in FIG. 3.

As shown in FIG. 9, the semiconductor chip 10B includes the semiconductor substrate 11 having the surface lit, and the wiring layer RDL formed on the surface lit. Also, the semiconductor chip 10B has an insulating layer 12 arranged so as to cover the wiring layer RDL, and having the surface 12b facing the surface 11t of the semiconductor substrate 11, the surface 12t opposite the surface 12b, and the plurality of protruding electrodes 1BP electrically connected with the wiring layer RDL.

As shown in FIG. 14, the surface 12t of the insulating layer 12 includes the side 1s1 extending in the X direction, the side 1s2 located on the opposite side of the side 1s1, the region R7 located between the side 1s1 and the side 1s2, the region R8 located between the side 1s1 and the region R7, and the region R3 located between the side 1s1 and the region R8.

The plurality of protruding electrodes 1BP include a protruding electrode BP7 arranged at a position overlapping the region R7 in plan view, a protruding electrode BP8 arranged at a position overlapping the region R8 in plan view, and a protruding electrode BP3 arranged at a position overlapping the region R3 in plan view.

Each of the plurality of protruding electrodes BP3 is electrically connected to the input/output circuit IO1 of the semiconductor chip 10B (refer to FIG. 4). Each of the plurality of protruding electrodes BP7 and the plurality of protruding electrodes BP8 is electrically connected to a circuit (for example, the core circuit CC1 shown in FIG. 4) different from the input/output circuit IO1.

As shown in FIG. 15, the plurality of protruding electrodes BP7 are arranged at the pitch P77. The plurality of protruding electrodes BP8 are arranged at the pitch P88, which is narrower than the pitch P77. The plurality of protruding electrodes BP3 (refer to FIG. 14) are arranged at the pitch P33 (refer to FIG. 6), which is different from each of the pitches P77 and P88. In the Y direction perpendicular to the X direction, the component in the Y direction of the pitch P88 (distance P8Y) is smaller than the component in the Y direction of the pitch P77 (distance P7Y).

In the example shown in FIG. 15, the minimum pitch (pitch P78min) between one of the plurality of protruding electrodes BP7 and one of the plurality of protruding electrodes BP8 is equal to or greater than the pitch P88. Also, the minimum pitch (pitch P38min) between one of the plurality of protruding electrodes BP3 shown in FIG. 14 and one of the plurality of protruding electrodes BP8 is equal to or greater than the pitch P88 shown in FIG. 15. The pitch P78min shown in FIG. 15 is the minimum value of the pitch between one of the plurality of protruding electrodes BP7 and one, which is located next to the one of the plurality of protruding electrodes BP7, of the plurality of protruding electrodes BP8. Also, the pitch P38min shown in FIG. 14 is the minimum value of the pitch between one of the plurality of protruding electrodes BP3 and one, which is located next to the one of the plurality of protruding electrodes BP3, of the plurality of protruding electrodes BP8.

Each of the distances PBX and P8Y shown in FIG. 15 is 92 μm. Therefore, the pitch P88 is 130 μm. The distance P7X shown in FIG. 15 is 92 μm, and the distance P7Y is 108 μm. Therefore, the pitch P77 is 142 μm. Also, the pitch P38min shown in FIG. 14 is equal to the pitch P88. The pitch P78min shown in FIG. 15 is wider than the pitch P11 and is 124 μm.

In this way, in the case of the semiconductor device PKG3, a plurality of protruding electrodes BP7 are provided in the region R7 to easily adjust the distance between the plurality of protruding electrodes BP8 and the plurality of protruding electrodes BP3. As a result, the distance between the plurality of protruding electrodes BP3 shown in FIG. 14 and the plurality of protruding electrodes BP8 is controlled to an appropriate distance, so it is possible to suppress the occurrence of the voids mentioned above.

As explained in FIG. 6 regarding the relationship between the pitch P11 and the pitch P22, if the component in the Y direction of the pitch P88 (distance P6Y) shown in FIG. 15 is shorter than the component in the Y direction of the pitch P77 (distance P7Y), the value of the component in the X direction of the pitch P77 (distance P7X) can be set arbitrarily. In the example shown in FIG. 15, the pitch P88 is narrower than the pitch P77. However, as a modified example, depending on the value of the component in the X direction of the pitch P77 (distance P7X), there may be cases where the pitch P77 is the same as the pitch P88, or the pitch P88 is wider than the pitch P77. As shown in FIG. 15, it is easier to adjust to fill the gap when the pitch P77 is wider than the pitch P88.

In this modified example, as shown in FIG. 14, the surface 12t of the insulating layer 12 further includes the region R9 located between the side 1s2 and the region R7, and the region R6 located between the side 1s1 and the region R9.

The plurality of protruding electrodes 1BP further include a protruding electrode BP7 arranged at a position overlapping the region R7 in plan view, a protruding electrode BP9 arranged at a position overlapping the region R9 in plan view, and a protruding electrode BP6 arranged at a position overlapping the region R6 in plan view.

Each of the plurality of protruding electrodes BP6 is electrically connected to the input/output circuit IO1 of the semiconductor chip 10B (refer to FIG. 4). Each of the plurality of protruding electrodes BP7 and the plurality of protruding electrodes BP9 is electrically connected to a circuit (for example, the core circuit CC1 shown in FIG. 4) different from the input/output circuit IO1.

As shown in FIG. 15, the plurality of protruding electrodes BP9 are arranged at a pitch P99, which is narrower than the pitch P77. The plurality of protruding electrodes BP6 are arranged at a pitch P66 (refer to FIG. 10) that is different from each of pitches P77 and P99. In the Y direction perpendicular to the X direction, the component (distance P9Y) along the Y direction of the pitch P99 is smaller than the component (distance P7Y) along the Y direction of the pitch P77.

Note that, as with the relationship between the pitch P11 and the pitch P22 explained in FIG. 6, if the component (distance P9Y) in the Y direction of the pitch P99 shown in FIG. 15 is shorter than the component (distance P7Y) in the Y direction of the pitch P77, the value of the component (distance P7X) in the X direction of the pitch P77 can be arbitrarily set. In the example shown in FIG. 15, the pitch P99 is narrower than the pitch P77. However, as a modified example, depending on the value of the component (distance P7X) in the X direction of the pitch P77, there may be cases where the pitch P99 is the same as the pitch P77, or the pitch P99 is wider than the pitch P77. As shown in FIG. 15, it is easier to adjust to fill the gap when the pitch P77 is wider than the pitch P99.

Also, in the example shown in FIG. 15, the minimum pitch (pitch P79min) between one of the plurality of protruding electrodes BP7 and one of the plurality of protruding electrodes BP9 is equal to or greater than the pitch P99. Also, the minimum pitch (pitch P69min) between one of the plurality of protruding electrodes BP6 shown in FIG. 14 and one of the plurality of protruding electrodes BP9 is equal to or greater than the pitch P99 shown in FIG. 15. The pitch P79min shown in FIG. 15 is the minimum value of the pitch between one of the plurality of protruding electrodes BP7 and one, which is located next to the one of the plurality of protruding electrodes BP7, of the plurality of protruding electrodes BP9. Also, the pitch P69min shown in FIG. 14 is the minimum value of the pitch between one of the plurality of protruding electrodes BP6 and one, which is located next to the one of the plurality of protruding electrodes BP6, of the plurality of protruding electrodes BP9.

Each of the distances P9X and P9Y shown in FIG. 15 is 92 μm. Therefore, the pitch P99 is 130 μm. The distance P7X shown in FIG. 15 is 92 μm, and the distance P7Y is 108 μm. Therefore, the pitch P77 is 142 μm. Also, the pitch P69min shown in FIG. 14 is equal to the pitch P99. The pitch P79min shown in FIG. 15 is wider than pitch P11 and is 124 μm.

The semiconductor device PKG3 of this modified example has an area R7 for array adjustment arranged between areas R8 and R9. Also, in the case of the semiconductor device PKG3, areas R8 and R3 are adjacent to each other, and areas P9 and P6 are adjacent to each other. Therefore, compared with the semiconductor device PKG1 shown in FIG. 5 or the semiconductor device PKG2 shown in FIG. 11, it is advantageous in that the arrangement space of the protruding electrodes BP7 for array adjustment can be reduced.

On the other hand, in terms of the ease of adjusting the spacing between the protruding electrodes, the semiconductor device PKG1 shown in FIG. 5 or the semiconductor device PKG2 shown in FIG. 11 is advantageous.

### <Method of Manufacturing Semiconductor Device>

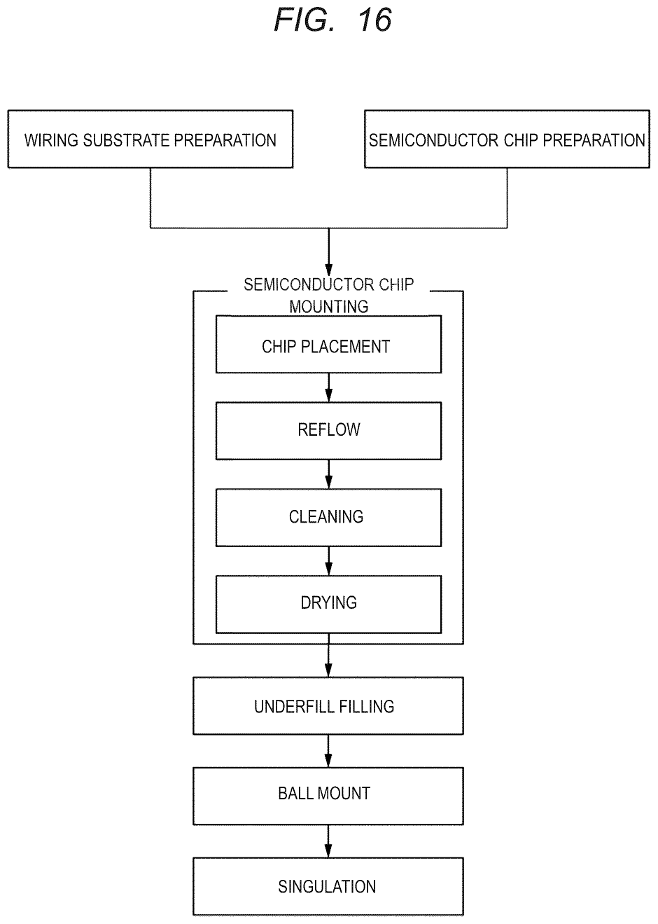

Next, a brief explanation will be given of a method of manufacturing the semiconductor device described above. Here, as a representative example, the method of manufacturing the semiconductor device PKG1 shown in FIG. 5 will be explained. Also, the explanation will focus on the drying process related to the cause of the voids mentioned above, and the explanation of other processes will be brief. FIG. 16 is an explanatory diagram showing an example of the flow of a method of manufacturing the semiconductor device shown in FIG. 3.

The method of manufacturing the semiconductor device of the present embodiment, as shown in FIG. 16, includes a wiring substrate preparation process, a semiconductor chip preparation process, a semiconductor chip mounting process, an underfill filling process, a ball mount process, and a singulation process.

In the wiring substrate preparation process shown in FIG. 16, a wiring substrate 20 shown in FIG. 3 is prepared. Note that the wiring substrate prepared in this process is a so-called multi-piece substrate in which a plurality of wiring substrates 20 is integrally formed.

In the semiconductor chip preparation process shown in FIG. 16, the semiconductor chip 10 shown in FIGS. 1, 3, 4, 5, 6, 9, and 10 is prepared. As a modified example, in this process, a semiconductor chip 10A shown in FIGS. 11 and 12 may be prepared. Furthermore, as another modified example, there may be a case where the semiconductor chip 10B shown in FIGS. 14 and 15 is prepared in this process.

The semiconductor chip mounting process shown in FIG. 16 includes a chip placement process, a reflow process, a cleaning process, and a drying process.

In the chip placement process, as shown in FIG. 3, the semiconductor chip 10 is placed on the upper surface 20t of the wiring substrate 20. In this process, the plurality of terminals 2PD formed on the wiring substrate 20 and the plurality of protruding electrodes 1BP are positioned so as to face each other. Also, for example, flux or a paste material mixed with solder may be pre-applied to each exposed surface of the plurality of terminals 2PD. Flux is a material containing an activator that facilitates the bonding of solder and terminal 2PD.

In the reflow process performed after the chip placement process, the temperature of the protruding electrode 1BP is heated to the temperature at which the solder contained in the protruding electrode 1BP melts, and after the solder and terminal 2PD have wetted, the temperature is lowered. By this process, the plurality of protruding electrodes 1BP and the plurality of terminals 2PD are each bonded. At this time, for example, residues such as flux may adhere to the surroundings of the protruding electrode 1BP.

To prevent residues such as flux from remaining in the product, a cleaning process is performed after the reflow process. In the cleaning process, water or a cleaning solution with a drug added to water is continuously supplied to the gap between the semiconductor chip 10 and the wiring substrate 20 shown in FIG. 3. If the moisture supplied in this process remains in the product, it can cause the aforementioned voids.

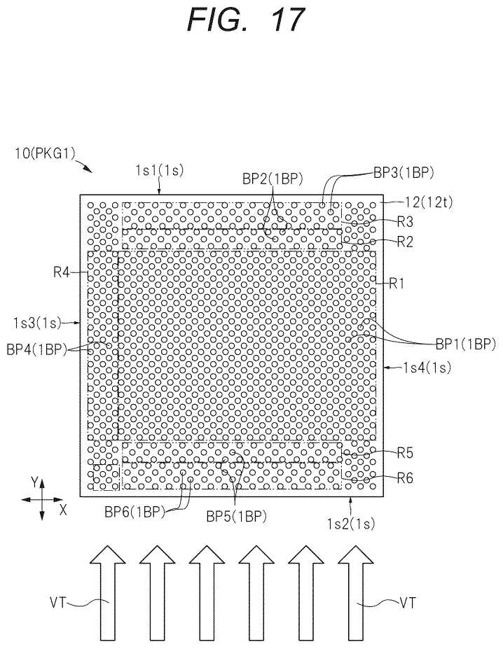

Next, in the drying process, moisture is removed by continuously supplying air (for example, warm air) to the gap between the semiconductor chip 10 and the wiring substrate 20 shown in FIG. 3. FIG. 17 is a plan view schematically showing the direction of sending wind in the drying process shown in FIG. 16.

In the case of the present embodiment, as schematically shown with arrows in FIG. 17, air VT is continuously sent in the direction from the side 1s2 to the side 1s1 of the semiconductor chip 10. In this case, drying proceeds from the position closer to the side 1s2, and the drying process ends when drying is completed up to the side 1s1.

The moisture remaining around the protruding electrode 1BP may be removed by evaporation, but it may also be removed by being pushed out in the direction of the wind. According to the study by the present inventors, in the case of the drying method shown in FIG. 17, not only the region closer to the side 1s2 (corresponding to the blank region RBL2 shown in FIG. 8) but also the region closer to the side 1s1 (corresponding to the blank region RBL1 shown in FIG. 8) can suppress the occurrence of voids. More specifically, in the case of the semiconductor chip 10 shown in FIG. 17, the occurrence of voids can be suppressed not only at the boundary between the region R6 and the region R5 and the boundary between the region R5 and the region R1, but also at the boundary between the region R1 and the region R2 and the boundary between the region R2 and the region R3.

The same applies to the case of the semiconductor chip 10A shown in FIG. 11. Also, in the case of the semiconductor chip 10B shown in FIG. 15, the occurrence of voids can be suppressed at each of the boundaries between the region R6 and the region R9, the region R9 and the region R7, the region R7 and the region R8, and the region R8 and the region R3.

From these results, the structures shown in FIG. 5, FIG. 11, or FIG. 15 can particularly suppress the occurrence of voids when the drying method of continuously sending air VT from the side 1s2 side to the side 1s1 side as shown in FIG. 17 is applied.

Next, in the underfill filling process, a paste-like or liquid resin is supplied to the gap between the semiconductor chip 10 and the wiring substrate 20 shown in FIG. 3, and the plurality of protruding electrodes 1BP is sealed. In the case of the present embodiment, since the drying process is completed before the underfill filling process and the remaining moisture is removed, it is possible to prevent the occurrence of voids after the underfill filling process.

Next, in the singulation process, the wiring substrate (multi-piece substrate) is divided to obtain a plurality of semiconductor devices PKG1.

Although the invention made by the present inventor has been specifically described based on the embodiment, the present invention is not limited to the above embodiment, and it is needless to say that various modifications can be made without departing from the gist thereof.

What is claimed is:

1. A semiconductor device comprising:
a wiring substrate;
a semiconductor chip mounted on the wiring substrate via a plurality of protruding electrodes; and
a first insulating material arranged between the semiconductor chip and the wiring substrate, and sealing the plurality of protruding electrodes,
wherein the semiconductor chip includes:
a semiconductor substrate having a first surface;
a first wiring layer formed on the first surface;
a second insulating layer arranged so as to cover the first wiring layer, the second insulating layer having a second surface facing the first surface of the semiconductor substrate and a third surface opposite the second surface; and
the plurality of protruding electrodes electrically connected with the first wiring layer,
wherein, in a plan view, the third surface of the second insulating layer includes:
a first side extending in a first direction;
a second side opposite the first side;
a first region located between the first side and the second side;
a second region located between the first side and the first region, and located next to the first region; and
a third region located between the first side and the second region, and located next to the second region,
wherein, in plan view, the plurality of protruding electrodes includes:
a plurality of first protruding electrodes arranged at positions overlapping the first region;
a plurality of second protruding electrodes arranged at positions overlapping the second region; and
a plurality of third protruding electrodes arranged at positions overlapping the third region,
wherein each of the plurality of third protruding electrodes is electrically connected with a first circuit of the semiconductor chip,
wherein each of the plurality of first protruding electrodes and the plurality of second protruding electrodes is electrically connected with a circuit different from the first circuit,
wherein the plurality of first protruding electrodes is arranged at a first pitch,
wherein the plurality of second protruding electrodes is arranged at a second pitch,
wherein the plurality of third protruding electrodes is arranged at a third pitch different from each of the first pitch and the second pitch, and
wherein a component in a second direction, which is perpendicular to the first direction, of the second pitch is larger than a component in the second direction of the first pitch.

2. The semiconductor device according to claim 1, wherein the plurality of third protruding electrodes of the plurality of protruding electrodes includes a protruding electrode arranged at a position closest to the first side.

3. The semiconductor device according to claim 2, wherein the first circuit is an input/output circuit for an electrical signal.

4. The semiconductor device according to claim 1, wherein the plurality of second protruding electrodes is arranged in three or more rows in the second direction.

5. The semiconductor device according to claim 1, wherein each of the plurality of first protruding electrodes and the plurality of second protruding electrodes is arranged in a staggered manner.

6. The semiconductor device according to claim 1,
wherein a minimum pitch between one of the plurality of first protruding electrodes and one, which is located next to the one of the plurality of first protruding electrodes, of the plurality of second protruding electrodes is equal to or greater than the first pitch, and
wherein a minimum pitch between one of the plurality of third protruding electrodes and one, which is located next to the one of the plurality of third protruding electrodes, of the plurality of second protruding electrodes is equal to or greater than the first pitch.

7. The semiconductor device according to claim 6, wherein a maximum pitch between one of the plurality of first protruding electrodes and one, which is located next to the one of the plurality of first protruding electrodes, of the plurality of second protruding electrodes is equal to or less than the second pitch.

8. The semiconductor device according to claim 6, wherein a maximum pitch between one of the plurality of third protruding electrodes and one, which is located next to the one of the plurality of third protruding electrodes, of the plurality of second protruding electrodes is equal to or less than the second pitch.

9. The semiconductor device according to claim 1,
wherein, in plan view, the third surface of the second insulating layer further includes:
a third side extending in the second direction; and
a fourth region located between the third side and the first region,
wherein, in plan view, the plurality of protruding electrodes includes a plurality of fourth protruding electrodes arranged at positions overlapping the fourth region,
wherein each of the plurality of fourth protruding electrodes is electrically connected with a second circuit of the semiconductor chip,
wherein each of the plurality of first protruding electrodes and the plurality of second protruding electrodes is electrically connected with the circuit different from the second circuit, and
wherein the plurality of fourth protruding electrodes is arranged at the first pitch.

10. The semiconductor device according to claim 9, wherein the component in the second direction of the first pitch is longer than a component in the first direction of the first pitch.

11. The semiconductor device according to claim 10,
wherein each of the plurality of first protruding electrodes is connected with either a power-supply potential supply path that supplies a power-supply potential to the circuit, or a reference potential supply path that supplies a reference potential to the circuit, and
wherein the wiring substrate includes a second wiring layer where a plurality of terminals connected to any of the plurality of first protruding electrodes, the plurality of second protruding electrodes and the plurality of third protruding electrodes is arranged,
wherein the plurality of terminals includes:
a plurality of power-supply potential terminals electrically connected to the power-supply potential supply path; and
a plurality of reference potential terminals electrically connected to the reference potential supply path, and
wherein the second wiring layer includes:
a power-supply potential wiring connected to each of the plurality of power-supply potential terminals arranged in the first direction, and extending in the first direction; and
a reference potential wiring connected to each of the plurality of reference potential terminals arranged in the first direction, and extending in the first direction.

12. The semiconductor device according to claim 11,
wherein an outer edge of each of the plurality of power-supply potential terminals forms an arc shape, and
wherein a width of the power-supply potential wiring in the second direction is equal to or greater than a radius of each of the plurality of power-supply potential terminals.

13. The semiconductor device according to claim 11,
wherein an outer edge of each of the plurality of reference potential terminals forms an arc shape, and
wherein a width of the reference potential wiring in the second direction is equal to or greater than a radius of each of the plurality of reference potential terminals.

14. A semiconductor device comprising:
a wiring substrate;
a semiconductor chip mounted on the wiring substrate via a plurality of protruding electrodes; and
a first insulating material arranged between the semiconductor chip and the wiring substrate, and sealing the plurality of protruding electrodes,
wherein the semiconductor chip includes:
a semiconductor substrate having a first surface;
a first wiring layer formed on the first surface;
a second insulating layer arranged so as to cover the first wiring layer, the second insulating layer having a second surface facing the first surface of the semiconductor substrate and a third surface opposite the second surface; and
the plurality of protruding electrodes electrically connected with the first wiring layer,
wherein, in a plan view, the third surface of the second insulating layer includes:
a first side extending in a first direction;
a second side opposite the first side;
a first region located between the first side and the second side;
a second region located between the first side and the first region; and
a third region located between the first side and the second region,
wherein, in plan view, the plurality of protruding electrodes includes:
a plurality of first protruding electrodes arranged at positions overlapping the first region;
a plurality of second protruding electrodes arranged at positions overlapping the second region; and
a plurality of third protruding electrodes arranged at positions overlapping the third region,
wherein each of the plurality of third protruding electrodes is electrically connected with a first circuit of the semiconductor chip,
wherein each of the plurality of first protruding electrodes and the plurality of second protruding electrodes is electrically connected with a circuit different from the first circuit,
wherein the plurality of first protruding electrodes is arranged at a first pitch,
wherein the plurality of second protruding electrodes is arranged at a second pitch,
wherein the plurality of third protruding electrodes is arranged at a third pitch different from each of the first pitch and the second pitch, and
wherein a component in a second direction, which is perpendicular to the first direction, of the second pitch is smaller than a component in the second direction of the first pitch.
